(19) United States
(12) Patent Application Publication
(10) Pub. No.: US 2022/0132629 A1
(43) Pub. Date: Apr. 28, 2022

(54) ELECTRIC HEATER DEVICE SEMI-FINISHED PRODUCT, ELECTRIC HEATER DEVICE AND MANUFACTURING PROCESSES

(71) Applicant: ELTEK S.p.A., Casale Monferrato (Alessndria) (IT)

(72) Inventors: Alberto BARBANO, Casale Monferrato (Alessandria) (IT); Mauro ZORZETTO, Casale Monferrato (Alessandria) (IT); Marco PIZZI, Casale Monferrato (Alessandria) (IT); Luca VERCELLOTTI, Casale Monferrato (Alessandria) (IT)

(21) Appl. No.: 17/428,516

(22) PCT Filed: Feb. 5, 2020
(86) PCT No.: PCT/IB2020/050925

§ 371 Date: Aug. 4, 2021

(30) Foreign Application Priority Data
Feb. 6, 2019 (IT) 102019000001745

(51) Int. Cl. H05B 3/26

(52) U.S. Cl. CPC H05B 3/267; H05B 2203/016; H05B 2203/02

(57) ABSTRACT

A semi-finished product of an electric heater device has a casing body (2) defining a housing for at least one electric heater. The casing body (2) has a first or predefined configuration, in particular a substantially planar, or plate-like, or two-dimensional configuration, and is prearranged for being folded in substantially predetermined areas (1a), which define in the casing body (2) a plurality of regions (4, 5, 6) that are at least in part relatively stiff and are suitable to be folded with respect to one another in one said folding area (1a). In this way, a second or different configuration, in particular a substantially three-dimensional configuration, can be bestowed upon the casing body (2).

### FIELD OF THE INVENTION

The present invention relates to electric heater devices and to the corresponding manufacturing methods, and more in particular to devices based upon the use of polymer-based materials (or comprising at least one polymer), distinguished by an electrical resistance, in particular an electrical resistance with positive temperature coefficient, i.e., having a PTC effect.

The invention has been developed with particular reference to the production of electric heater devices that are to be used on vehicles, such as heaters for tanks, heaters for filters, heaters for fluid ducts, heaters for batteries, heaters for substances that are subject to freezing or that vary their characteristics as a function of temperature, or again heaters used for heating aeriforms, such as air for environments or air subject to forced circulation on the surface of the aforesaid heaters.

The invention finds a preferred application in the sector of components of tanks or ducts that are to come into contact with a liquid, for example a liquid used in a vehicle, such as a liquid necessary for operation of an internal-combustion engine, or a liquid necessary for operation of a system for treatment or reduction of exhaust gases of an internal-combustion engine, including water-injection or anti-detonant-injection systems, or a washing liquid, such as a liquid for washing sensors and/or windows or windscreens (for example, water for washing external sensors, such as video cameras and/or optical sensors).

The heater devices and the semi-finished products according to the invention may in any case also be applied in contexts different from the preferential ones referred to above.

### Prior Art

Production of electric heater devices that use a plurality of heating bodies made of a material having a PTC effect is widespread, given the functional characteristics of such materials. In some cases, the heater device includes a single heating body made of a material having a PTC effect with opposite surfaces having a relatively wide area, associated to which are two electrodes of accordingly large dimensions, constituted by metal plates. In other cases, the heater device includes, instead, a plurality of heating bodies of relatively small dimensions, with respective electrodes connected to electrical-connection bodies. Alongside more traditional ceramic-based materials, there have in recent times appeared resistive polymeric materials, in particular PTC-effect ones, which can be obtained more easily in different forms and can be moulded directly between corresponding electrodes. Notwithstanding this, the production of heater devices that integrate a number of heating bodies made of PTC-effect polymeric material is still generally complicated, and the same may be said as regards integration of the aforesaid heater devices in more complex functional components.

In the sector of motor-vehicle components, PTC-effect heater devices are typically provided, which are substantially rigid and specifically shaped. For instance, WO2017077447 A describes a heater device designed for integration in a component of a vehicle tank, in particular a component having a generally cylindrical shape. The device comprises a plurality of heating bodies made of a PTC-effect polymeric material, each of which is set between a first electrode and a second electrode, with the first and second electrodes associated to the various heating bodies that are connected to a first electrical-connection body and a second electrical-connection body, respectively. The PTC-effect polymeric material that is necessary for formation of each heating body is overmoulded between facing surfaces of the first and second electrodes, and then an electrically insulating plastic material is overmoulded on the electrodes, with interposition of the corresponding heating bodies, and on the connection bodies.

The first electrodes with their corresponding connection body, on one side, and the second electrodes with their corresponding connection body, on the other side, can be defined in a single piece, via operations of blanking starting from respective plane metal plates. The two blanked plane pieces are set in parallel positions in a mould, via which the PCT-effect polymeric material is moulded only between the facing surfaces of the electrodes defined by each plane piece. In this way, a substantially plane semi-finished product is obtained, which is then subjected to folding operations, in joining areas between the electrodes and the corresponding connection bodies, in such a way that the semi-finished product itself will assume an approximately cylindrical configuration. On the folded semi-finished product there is then overmoulded the plastic material that forms the casing body, here corresponding to the body of the tank component, to form the corresponding rigid walls, which extend both horizontally and vertically, thus giving rise to a certain volume.

A further typical problem of known heaters of the aforesaid type is represented by detachment of the PTC-effect polymeric material from the corresponding metal electrodes, with consequent operating faults, where this drawback may be a consequence of the different degrees of expansion and contraction of the different materials, such as a polymer and a metal, during the cycles of heating and subsequent cooling, in particular during operation and/or as a result of environmental conditions. This drawback may be more easily noted in heaters of large dimensions, such as heaters for vehicle tanks, where consequently the phenomena of expansion of the materials are accentuated, in particular in the directions of width and length of the heater device (this on account of the fact that in this case the expansions “add up”, for example causing dimensional variations that are very accentuated in the peripheral areas or in the end areas opposite to the areas of mechanical fixing or constraint of the device).

A further related problem is represented by the mechanical stresses that are set up between the heating bodies and the corresponding casing, in particular in the presence of different expansions or dimensional variations due to cycles of heating and subsequent cooling.

As may be noted, the modalities of production of the heater device and/or its integration in a different component are relatively laborious and may give rise to malfunctioning.

### OBJECT AND SUMMARY OF THE INVENTION

In view of what has been set forth above, the present invention has basically the aim of simplifying production of electric heater devices, in particular ones that use PTC-effect polymeric materials, and/or integration thereof in other components.

The above and other aims still, which will emerge clearly hereinafter, are achieved according to the present invention by a semi-finished product of an electric heater device, by an electric heater device, and by corresponding manufacturing methods that present the characteristics specified in the annexed claims. The claims form an integral part of the technical teaching provided herein in relation to the invention.

### BRIEF DESCRIPTION OF THE DRAWINGS

Further aims, characteristics, and advantages of the present invention will emerge clearly from the ensuing detailed description, with reference to the annexed drawings, which are provided purely by way of non-limiting example and in which:

FIGS. 1 and 2 are schematic perspective views, from different angles, of a semi-finished product of an electric heater device according to possible embodiments of the invention;

FIG. 3 is a partially exploded schematic view of a semi-finished product of the type illustrated in FIGS. 1 and 2;

FIGS. 4 and 5 are exploded schematic views, from different angles, of a semi-finished product of the type illustrated in FIGS. 1 and 2;

FIG. 6 is an exploded schematic view of electrical parts of a semi-finished product of the type illustrated in FIGS. 1 and 2;

FIG. 7 is a schematic perspective view of a further semi-finished product of an electric heater device according to possible embodiments of the invention;

FIG. 8 is an exploded schematic view of a semi-finished product of the type illustrated in FIG. 7;

FIG. 9 is a schematic perspective view of a further semi-finished product of an electric heater device according to possible embodiments of the invention;

FIG. 10 is an exploded schematic view of a semi-finished product of the type illustrated in FIG. 9;

FIG. 11 is a schematic perspective view of electrical parts connected together of a semi-finished product of an electric heater device according to possible embodiments of the invention;

FIG. 12 is a schematic perspective view of a body part of a semi-finished product of an electric heater device according to possible embodiments of the invention;

FIGS. 13 and 14 are schematic perspective views, from different angles, of a electric heater device according to possible embodiments of the invention;

FIG. 15 is a partial and schematic representation of a possible step of assembly of an electric heater device according to possible embodiments of the invention;

FIGS. 16 and 17 are schematic perspective views of a further semi-finished product of an electric heater device according to possible embodiments of the invention;

FIGS. 18 and 19 are details at an enlarged scale of FIGS. 16 and 17, respectively;

FIG. 20 is a schematic perspective view of an electric heater device according to further possible embodiments of the invention;

FIGS. 21 and 22 are details at an enlarged scale of FIG. 20;

FIG. 23 is a schematic perspective view of an electric heater device according to further possible embodiments of the invention;

FIGS. 24 and 25 are details at an enlarged scale of FIG. 23;

FIGS. 26 and 27 are schematic perspective views, from different angles, of a further semi-finished product of an electric heater device according to possible embodiments of the invention;

FIGS. 28 and 29 are details at an enlarged scale of FIGS. 26 and 27, respectively;

FIG. 30 is an exploded schematic view of a semi-finished product of the type illustrated to FIGS. 26 and 27;

FIG. 31 is a schematic perspective view of electrical parts connected together of a semi-finished product of an electric heater device according to possible embodiments of the invention;

FIG. 32 is a schematic perspective view, partially sectioned, of a part of a semi-finished product of an electric heater device according to possible embodiments of the invention;

FIG. 33 is a schematic perspective view of an electric heater device according to further possible embodiments of the invention;

FIG. 34 is a detail at an enlarged scale of FIG. 33;

FIGS. 35 and 36 are partial and schematic perspective views, aimed at exemplifying a step of assembly of an electric heater device according to further possible embodiments of the invention;

FIGS. 37, 38, and 39 are schematic perspective views that represent possible variant embodiments of the invention;

FIGS. 40-41, 42-43, 44-45, and 46-47 are schematic illustrations of further variants of semi-finished product and heater devices that can be obtained with these variants, respectively; and

FIG. 48 is a schematic illustration of a further variant of semi-finished product.

### DESCRIPTION OF PREFERRED EMBODIMENTS OF THE INVENTION

Reference to “an embodiment” or “one embodiment” in the framework of the present description is intended to indicate that a particular configuration, structure, or characteristic described in relation to the embodiment is comprised in at least one embodiment. Hence, phrases such as “in an embodiment”, “in one embodiment”, and the like that may be present in various points of the present description do not necessarily refer to one and the same embodiment. Moreover, particular conformations, structures, or characteristics defined in this description may be combined in any adequate way in one or more embodiments, even different from the ones represented. The reference numbers and spatial references (such as “upper”, “lower”, “top”, “bottom”, etc.) used herein are provided merely for convenience and hence do not define the sphere of protection or the scope of the embodiments.

In the present description and in the attached claims, the generic term “material” is to be understood as including also mixtures, compositions, or combinations of a number of different materials (for example, multilayer structures or composite materials).

In the present description and in the attached claims, the term “mesh structure” is intended to indicate a structure distinguished by an alternation of full and empty parts, for example like a net, a mesh, a sieve, a woven fabric, a braid, etc. This structure may be formed by the criss-crossing or interweaving of a plurality of substantially threadlike elements, such as threads or wires, or else obtained by processing of a single starting element, for example a metal strap that is blanked and/or shaped and/or stretched in order to bestow thereon a meshed shape.

In the present description and in the attached claims, the term “semi-finished product” is intended to designate an intermediate product or component, which is to undergo further processing and/or can be used in the production of more complex products or articles, even of types that are very different from one another.

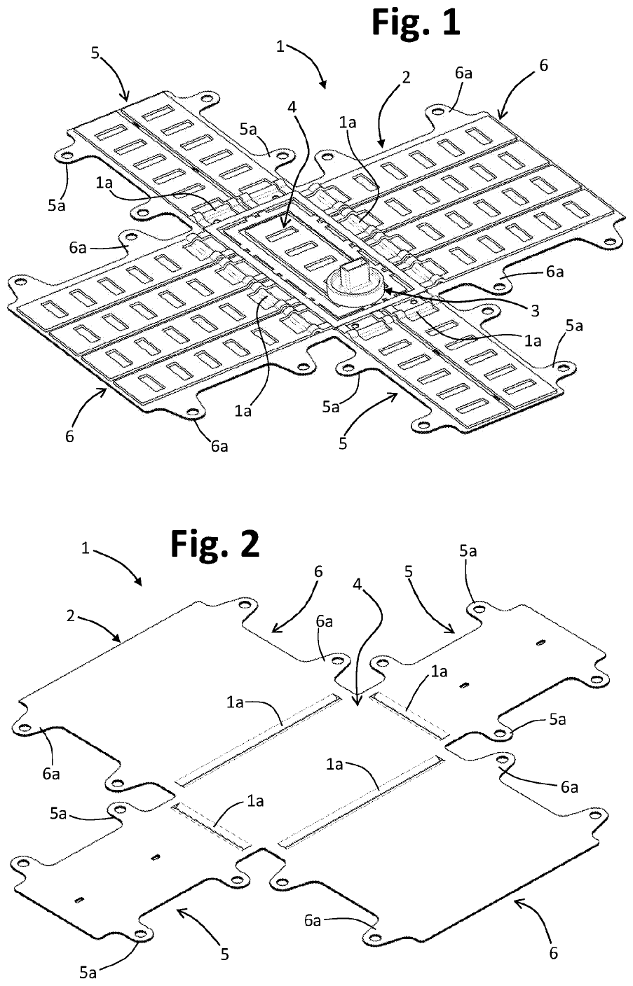

Represented schematically in FIGS. 1 and 2 is a first semi-finished product of an electric heater device according to possible embodiments of the invention, designated as a whole by 1, which comprises internal electrical parts and external casing parts. The semi-finished product 1 comprises a casing body designated by 2, preferably formed by a number of parts that are associated to one another and have a predefined manufacturing shape or configuration, i.e., a shape that is predefined at the end of its manufacturing process. In various preferential embodiments, the aforesaid predefined shape or configuration of the casing 2 of the semi-finished product is a substantially planar, or laminar (plate-like), or two-dimensional shape. The definition of “substantially planar, or laminar, or two-dimensional shape” is meant to comprise also casing shapes or configurations with some parts slightly inclined or slightly arched or curved, or shaped with a view to enabling a reduction in the overall dimensions, in particular in at least one first production step, such as a step of warehousing or transport of the semi-finished product.

In various embodiments, associated to the casing body 2 of the semi-finished product 1 is an electrical connector body, designated by 3.

Preferably, at least part of the planar casing body 2 is made of at least one polymer, such as a high-density polyethylene (HDPE), a polypropylene (PP), or a multilayer film. Preferably, at least part of the casing body 2 is made of a material that is compatible with and/or can be welded to the material of a different structure (such as a tank or a hydraulic duct) in which the heater device obtained starting from the semi-finished product 1 is to be mounted.

In various embodiments, such as the one represented, the casing body 2 has a central region or wall 4, extending outwards from the peripheral profile of which are a plurality of peripheral regions or walls 5 and 6, which have a relatively rigid structure. In the example, the central region 4 is substantially quadrangular, and four peripheral regions 5, 6 are provided, which are also substantially quadrangular. The number of the regions 5 and 6 may be smaller or greater than four, for example according to the peripheral profile of the central region 4: for instance, with a central region that is substantially triangular, three peripheral regions may be provided, whereas, with a hexagonal central region, six peripheral regions may be provided. This does not, however, constitute an essential characteristic in so far as the number of peripheral regions is not necessarily linked to the shape of the profile of the central region, as will be seen hereinafter.

With reference once again to the example illustrated, the central region 4 has a substantially rectangular peripheral profile, extending from which are two peripheral regions 5 and two peripheral regions 6, which have a width substantially corresponding to that of the shorter sides and of the longer sides, respectively, of the aforesaid rectangular profile. The peripheral regions 5, 6 extend in a respective longitudinal direction starting from the boundaries of the central region 4, preferably with one and the same length, even though this does not constitute an essential characteristic. The peripheral regions 5, 6 may also have a shape different from the substantially quadrangular one exemplified.

As will emerge more clearly hereinafter, in the present example the peripheral regions 5, 6 are designed to be folded at an angle relative to the central region 4 in order to obtain the three-dimensional body of an electric heater device, in particular a substantially rigid three-dimensional body, preferably defining a hollow volume.

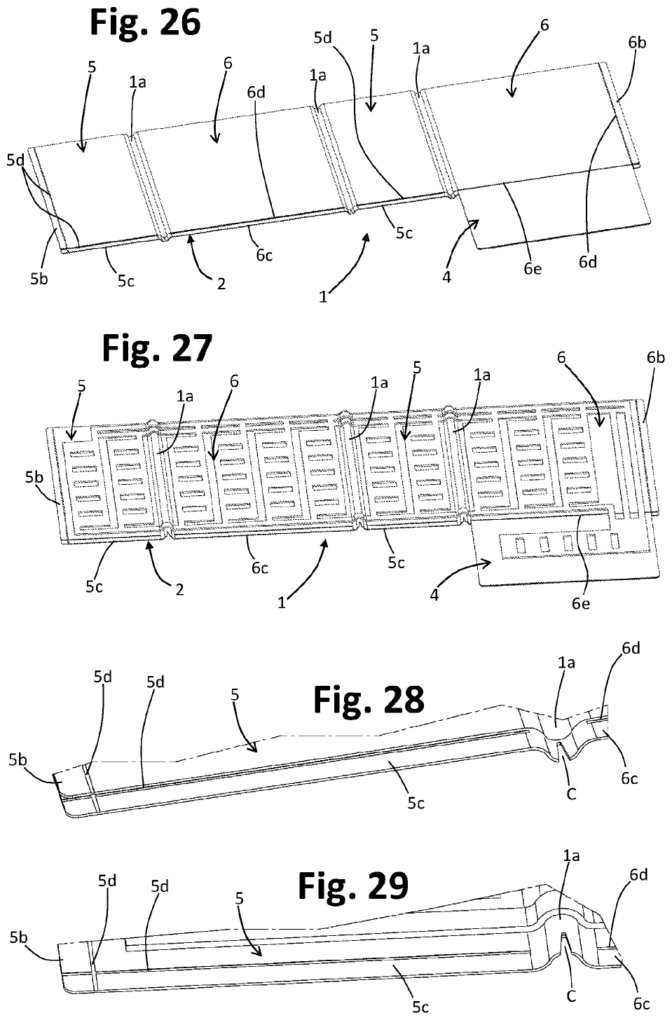

For this purpose, in various embodiments, the body 2 of the semi-finished product 1 is prearranged so as to present substantially predetermined folding areas, which are less stiff, designated by 1a. In embodiments of the type exemplified, with a quadrangular central region 4, the number of folding areas 1a may be equal to the number of the sides of the central region, i.e., equal to the number of the peripheral regions 5, 6, the folding areas 1a each being substantially defined between the central region 4 and a corresponding peripheral region 5 or 6. In other embodiments, for example of the type described hereinafter with reference to FIGS. 26-27, at least two peripheral regions may be directly contiguous to one another, with one of these regions that can be folded at an angle with respect to the other in order to obtain the three-dimensional body of an electric heater device, preferably a box-like or tubular three-dimensional body defining a hollow volume.

In various embodiments, such as the one exemplified, the folding areas 1a are constituted by suitable shapings of the body 2, which, for example, substantially form concavities or grooves, preferably having semicircular shapes. The areas 1a may be constituted by reductions in thickness of the body 2, or else by incisions made therein. The folding areas 1a may perform the function of articulated joint or elastic hinge.

As will be seen, prearrangement of the substantially predetermined folding areas of the casing body does not necessarily presuppose the presence of the aforesaid concave areas, or grooves, or reductions in thickness, or incisions.

For the purposes of formation of the aforesaid three-dimensional body of the heater device, it is preferable for the peripheral regions 5, 6 to be coupled together at least locally, following upon folding, in particular in order to guarantee stable maintenance of the three-dimensional shape. For this purpose, in various embodiments, the peripheral regions 5, 6 have purposely provided edges: with reference to the example illustrated in FIGS. 1 and 2, at each longitudinal side or edge of each peripheral region 5, 6 at least one coupling or fixing element is provided, such as an appendage or bracket, some of which are designated by 5a and 6a. In various embodiments, the at least one bracket 5a of a region 5 is to be coupled to the at least one bracket 6a of a contiguous region 6, as clarified hereinafter. As it can be inferred, the coupling or joining elements here represented by the bracket 5a and 6a are preferably defined by portions of the casing body 2 which have a reduced thickness with respect to those at which certain electric heaters are integrated, as describe below.

In various embodiments, at least one major side or face of the casing body 2 is substantially plane or smooth, even though this does not constitute an essential characteristic. Both of the major sides or faces of the casing body 2 may have an irregular surface, for example with reliefs defined by housings for electrical connections and/or for heating elements, the latter preferably being designed to increase the surface of contact with a fluid to be heated in order to improve heat exchange. In the example represented, the body 2 is substantially smooth at its face that is to constitute the inner surface of the three-dimensional body of the heater device, as highlighted in FIG. 2. Coupled, instead, to the opposite face of the body 2, visible in FIG. 1, is the connector body 3, which is to remain on the outside of the aforesaid three-dimensional body of the end device, i.e., on the outside of the volume defined by the three-dimensional body.

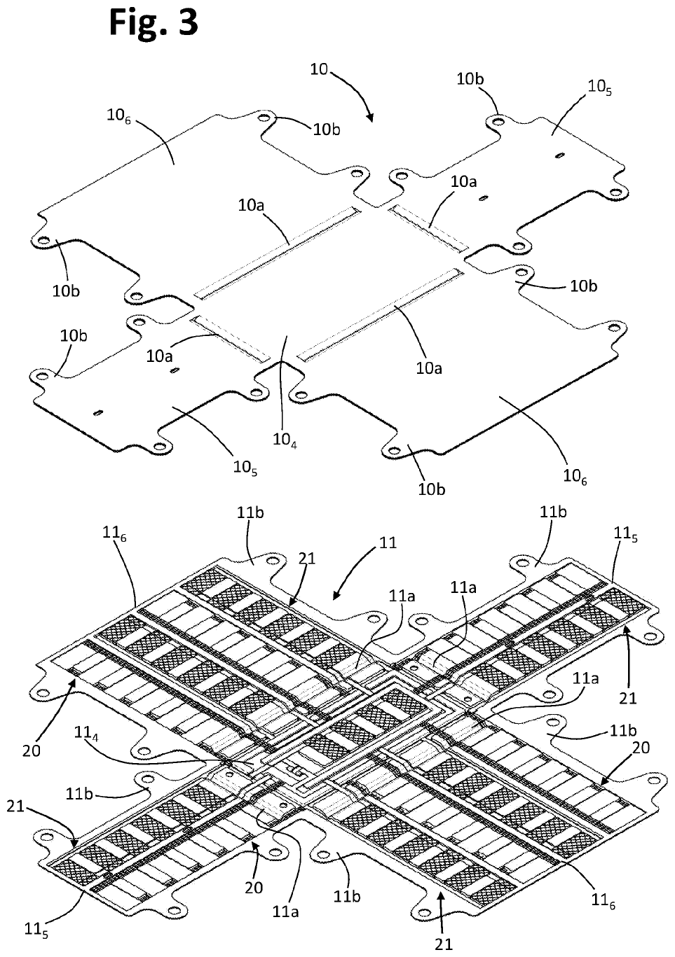

In FIG. 3, the semi-finished product 1 is represented partially exploded in order to render its internal electrical parts and its external casing parts visible. In various preferred embodiments, the casing body 2 of the semi-finished product 1 is made of two or more parts associated together, but in other embodiments the casing body may be formed at least in part via overmoulding of material on one or more electric heaters and/or corresponding electrical-connection elements. The casing body 2 is preferably of a hermetic type, i.e., conceived for enclosing the heater or heaters in a fluid-tight way. In the case of FIG. 3, designated by 10 and 11 are two casing parts, preferably each made of a single piece, which are to be coupled together with interposition of the electrical parts, the latter preferentially comprising a plurality of electric heaters, some of which are designated by 20 and 21, and a plurality of electrical conductors, described hereinafter.

In various embodiments, the two casing parts 10 and 11 have peripheral profiles that are substantially similar or corresponding to one another, and are preferably substantially similar or corresponding to the final peripheral profile of the casing body 2. In the example, this profile is a substantially shaped like a cross. For this purpose, in various embodiments, the parts 10 and 11 each have a central region, designated by 10₄ and 11₄, respectively, extending from which are corresponding peripheral regions, designated by 10₅, 10₆ and 11₅, 11₆, respectively. Preferentially, the casing parts 10 and 11 are provided with folding areas, designated by 10a and 11a, respectively, for example constituted by shapings of the aforesaid parts 10 and 11, which substantially form grooves or concavities, for example having a semicircular shape, it being, however, possible for them to have a cross section of some other shape suitable for the purpose (for example, formed by a series of linear and/or curved stretches). Also these folding areas 10a, 11a may be constituted by reductions of thickness of the parts 10, 11, or else by incisions made therein. In the condition where the two casing parts 10 and 11 are coupled together, the corresponding areas 10a and 11a are set on top of one another to form the folding areas 1a (FIG. 1) of the body 2 of the semi-finished product 1. Preferentially, at each longitudinal side or edge of each peripheral region 10₅, 10₆ and 11₅, 11₆ at least one coupling or fixing element is provided, such as at least one appendage or bracket, some of which are designated by 10b and 11b, respectively. In the condition where the two casing parts 10 and 11 are coupled together, the corresponding appendages 10b and 11b are preferably set on top of one another to obtain the brackets 5a and 6a (FIG. 1) of the body 2 of the semi-finished product 1.

In various embodiments, the casing parts 10 and 11 are made of electrically insulating plastic material and are fixed together, preferably in a fluid-tight way, via gluing or welding or engagement in order to enclose within them at least part of the aforesaid electrical parts. As has been mentioned, the aforesaid material is preferably a polymer, for example a high-density polyethylene (HDPE). Preferentially, the casing parts 10 and 11 are fixed together in a fluid-tight way at least along the respective peripheral profiles, there not being, however, excluded areas of mutual joining also in intermediate areas thereof.

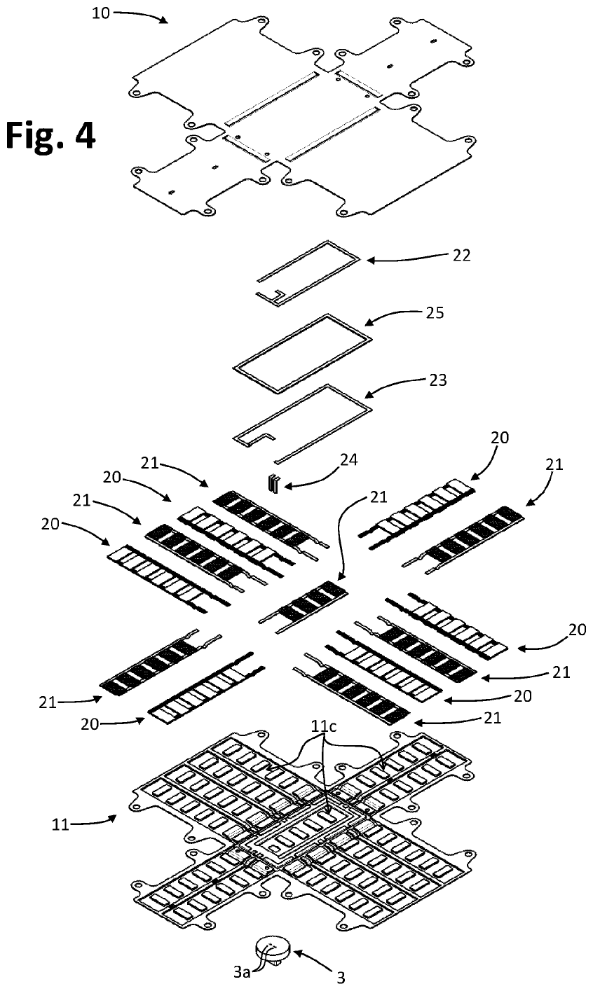

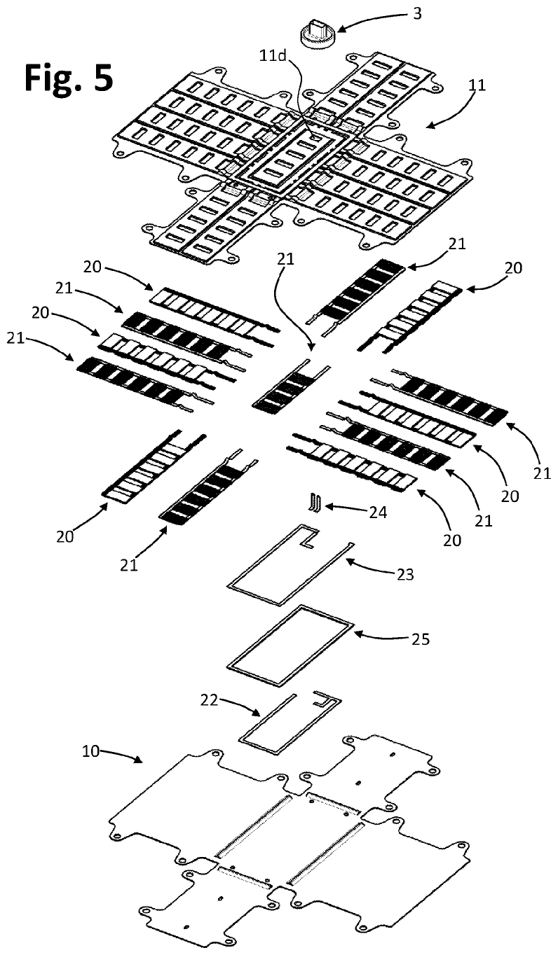

With reference also to FIGS. 4-5, in various embodiments, one casing part 10 has substantially flat or smooth surface, while the other casing part 11 is shaped so as to define at least one housing or seat—designated by 11c in FIG. 4—having a shape designed to receive electrical parts of the device, such as the heaters 20, 21 and corresponding electrical-connection elements. The aforesaid housing may even be constituted by a plurality of housings, even ones having shapes different from one another.

Preferentially, the aforesaid housing 11c has a plurality of portions, each defined at the corresponding central region 11₄ and the corresponding peripheral regions 11₅, 11₆ (see also FIG. 12) of the casing part 11. Preferentially, the housing 11c has a profile at least in part complementary to the heaters 20, 21 and/or to possible other electrical parts so as to ensure precise positioning thereof between the casing parts 10 and 11.

The two casing parts 10 and 11 may have substantially the same thickness or else have different thicknesses, for example with the casing part 11 thicker than the casing part 10, or vice versa. The casing parts may have only some parts with a different thickness, such as the aforesaid areas with reduced thickness in the aforesaid folding areas and/or in the areas for housing the heating elements, for example also to favour heat exchange. The choice of different thicknesses may depend upon the type of application, for example when—according to the type of installation in the working position of the heater device obtained from the semi-finished product 1—it is necessary to have a heat emission that is substantially the same on the inside and on the outside of a hollow volume defined by the heater device, or else it is necessary to favour heat emission on the inside or on the outside, or else only in some areas.

Of course, the thicknesses and materials used for providing the casing parts 10 and 11 may vary according to the need, provided that the material or materials are in any case such as to enable emission of the heat generated via the heaters 20, 21. In general, preferential thicknesses for the casing parts 10 and 11 may range from 0.1 mm to 2 mm. The combination of parts 10 and 11 of different thicknesses may be exploited for modulating the flexibility/stiffness of the semi-finished product 1 as a whole, according to the manufacturing needs.

In various preferential embodiments, at least one of the two casing parts 10, 11 comprises a polymer added with thermally conductive but electrically insulating filler or particles; i.e., the material of at least part of the casing body 2 of the semi-finished product 1 could be electrically insulating but thermally conductive (for example, an HDPE with a filler constituted by boron-nitride particles), in particular to improve heat exchange between the heaters 20, 21 and the environment external to the casing body 2, for example with respect to the liquid contained in a tank.

In the examples illustrated, the housing 11c for the internal electrical parts of the semi-finished product 1 is entirely defined in just one of the casing parts, in particular the part 11. However, in other embodiments, the two casing parts 10, 11 could define respective portions of the aforesaid housing 11c, with a substantially symmetrical conformation (i.e., with each casing part 10, 11 that defines substantially one half of the housing 11c) or else a substantially asymmetrical conformation.

One or both of the casing parts 10, 11 may advantageously be pre-formed, for example via moulding or via thermoforming, in order to define the housing 11c or a respective portion thereof. On the other hand, if at least one of the two casing parts 10, 11 is sufficiently thin, in particular in the form of a film of a relatively small thickness (for example, 0.35 mm), the shaping of the housing 11c or of a portion of housing in the film may be obtained using a template or equipment used for welding together the two casing parts 10, 11, preferably a template or equipment used for the purposes of vibration or ultrasound welding, or else welding of the remelting type, such as welding of the hot-blade type. For this purpose, the template or welding equipment, such as the sonotrode of vibration- or ultrasound-welding equipment, or else a heated plate of remelt- or hot-welding equipment, could be appropriately shaped, for example with a shape at least in part complementary to the one that the casing parts are to assume.

In various embodiments, such as the one exemplified, the semi-finished product 1 includes a plurality of electric heaters 20, 21, at least some of which are arranged in a configuration where they are set alongside one another, for example substantially parallel to one another, in at least one region 5, 6 of the body 2. The housing 11c defined by one of the two casing parts 10, 11, or by both of these parts (see what has been described above), is shaped accordingly. Preferentially, the semi-finished product 1 includes at least one heater in each region 4-6 thereof, even though this does not constitute an essential characteristic.

In the non-limiting example illustrated, thirteen heaters 20, 21 are provided, of which only one is located at the central region 4, two are located at each peripheral region 5, and four at each peripheral region 6. In various embodiments, such as the one exemplified in FIG. 5, each of the heaters 20, 21 comprises a plurality of heating elements connected together in parallel. However, in other embodiments, at least one or more heaters could comprise just one heating element, or else there could be provided a number of heating elements electrically connected in a different configuration, such as heaters the electrical resistances of which are connected at least in part in series together (for example, to form sets of heaters, the electrical resistances of which are connected together in series, these sets being then electrically connected together in parallel).

As has been said, the number and distribution of the heaters 20, 21 illustrated is provided merely by way of non-limiting example.

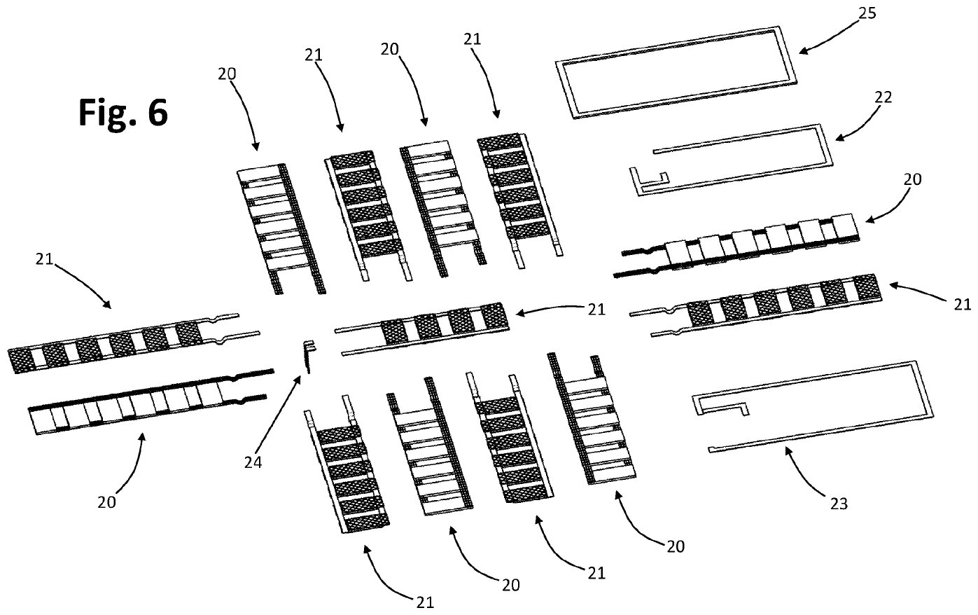

With reference also to FIG. 6, designated by 22 and 23 are two electrical conductors, made of electrically conductive material, to which respective electrical connection bodies of the heaters 20, 21, for example ones corresponding to the positive pole and to the negative pole, or in any case to two poles of the electric power supply, are to be connected.

Designated, instead, by 24 are two electrical terminals, each of which is to be electrically connected to a respective conductor 22 or 23. In the assembled condition of the semi-finished product 1, the terminals 24 preferentially project from the casing body 2 of the semi-finished product 1, in particular in a direction substantially orthogonal to a general plane identified by the casing body itself, through corresponding passages of the casing part 11.

The projecting portion of each terminal 24 may, for example, be inserted in a corresponding passage (3a, FIG. 4) defined by the connector body 3, with the latter that is preferably fixed in a fluid-tight way on the outer surface (i.e., opposite to the housing 11c) of the casing part 11, for instance, glued or welded thereon (see, for example, FIG. 1): in this way, at least the aforesaid projecting portions of the terminals 24 and the connector body 3 form an electrical connector for connection of the semi-finished product 1, i.e., of the heater device obtained therefrom, in particular an electrical connector designed to couple with the connector of a wiring external to the device 1.

In various embodiments, such as the ones so far exemplified, the conductors 22, 23 and the terminals 24 are obtained starting from a material in the form of a strap, for example a metal material, but obviously other embodiments are possible, for example with the conductors 22, 23 formed by electrical wires or by deposition of metal or electrically conductive polymeric material (for example, a polymer added with electrically conductive fillers or substances).

In various embodiments, the semi-finished product 1 comprises electrical-insulation means in order to prevent possible short-circuits between the conductors 22, 23, i.e., prevent accidental contacts between parts subjected to different voltages or electrical polarities: in the example represented, an insulating film or tape 25 is purposely provided, which is to be to at least in part laid on top of the conductor 23, as described more clearly hereinafter.

The electric heaters 20, 21 used in the semi-finished product 1 may be all of one and the same type, or else be of different types, for example in terms of dimensions and/or shape, or number of heating bodies, or else heat-emission power, for example for the purposes of a different distribution of heat.

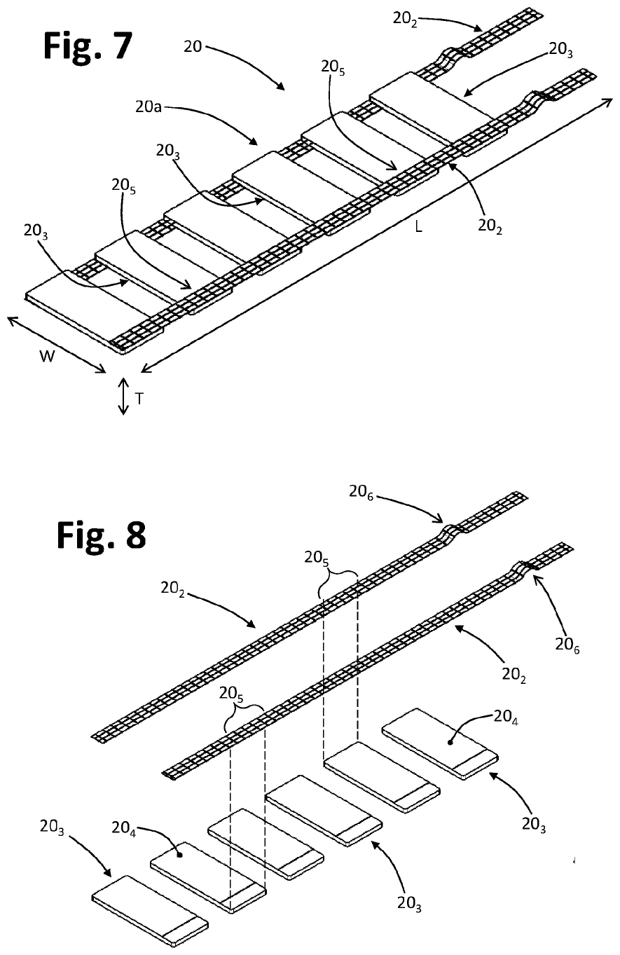

FIGS. 7 and 8 represent schematically a first type of electric heater 20, which can be used in various embodiments of the invention. Preferentially, the heater 20 is itself constituted by a portion or piece of a further semi-finished product, hereinafter referred to for simplicity as “heater semi-finished product”. It should hence be assumed that the heater 20 of FIG. 7 is constituted by a piece of limited length of the aforesaid heater semi-finished product.

In various preferential embodiments, the heater 20 (or else the semi-finished product from which it is obtained) has a structure 20a that extends in a direction of length L and a direction of width W and has a thickness T. Preferably, the structure 20a is relatively stiff in the direction of width W and substantially flexible or deformable in the direction of length L. In any case, preferentially, the structure 20a is more flexible, or more easily deformable, in the direction of length L than in the direction of width W.

In various embodiments, the structure 20a (i.e., the heater semi-finished product) can be rolled up or folded on itself. In other words, the structure 20a is sufficiently flexible or deformable in its direction of length as to enable it to be rolled up on itself to assume a more or less cylindrical shape, in particular to form a roll or the like, or else be folded on itself in opposite directions (i.e., in a zigzag fashion), to form a sort of more or less parallelepipedal stack.

The structure 20a comprises at least two electrical- and mechanical-connection bodies 20₂, which include at least two longitudinal elements made of electrically conductive material, which extend alongside one another in the direction of length L, preferably substantially parallel to one another, and which—as has been mentioned—are preferably flexible or deformable at least in the aforesaid direction of length L. The structure 20a further comprises a plurality of heating bodies 20₃, each preferably including at least one resistive material, preferably a material having a PTC effect, designated by 20₄ in FIG. 8, where the two electrical connection bodies 20₂ and some heating bodies 20₃ are visible in exploded view. As it can be clearly seen in FIG. 7, the two connection bodies comprise each a longitudinal element, that extends in the direction of length L and has a width decidedly smaller than the width of the heating bodies. From the same figure it is also well apparent how the two connection bodies 20₂ have respective parts that are intermediate to two successive heating bodies 3, in the direction of length L. As it can be noticed, the aforesaid intermediate parts of the connection bodies have a width that is a fraction of the width of the heating bodies and each intermediate part of a connection body extends at a distance from a corresponding intermediate part of the other connection body, in the direction of width (W).

Preferably the aforesaid intermediate parts of the connection bodies are in substantially staggered position. By virtue of this spaced-apart of staggered arrangement of the intermediate parts of the connection bodies, i.e., the parts thereof which extends between two successive heating bodies 3, these intermediate parts cannot touch each other during folding or curving of said intermediate parts of the connection bodies.

Also from FIG. 7 it may be well seen how, in the represented preferred not-deformed configuration represented, each of the bodies 20₂ extends substantially according to a respective plane, i.e., it is straight or flat either at the heating bodies 20₃ and at the aforesaid parts which are intermediate to the heating bodies 20₃.

In various embodiments, the material 20₄ constituting the heating body 20₃ is a polymer-based material (i.e., one comprising at least one polymer), preferably a composite material having a matrix formed by a polymer or by a mixture of a number of polymers and by a corresponding filler, for example an electrically conductive filler and/or a thermally conductive filler. In various preferred embodiments, the material 20₄ of a heating body 20₃ is a co-continuous polymeric composite with PTC effect, having a matrix that comprises at least two immiscible polymers and at least one electrically conductive filler in the matrix.

In preferred embodiments of this type, at least one of the immiscible polymers is high-density polyethylene (HDPE), and at least one other of the immiscible polymers is polyoxymethylene (POM). The electrically conductive filler is preferentially constituted by particles, which have micrometric or nanometric dimensions, preferably comprised between 10 nm and 20 μm, very preferably between 50 and 200 nm, possibly aggregated to form chains or branched aggregates of dimensions comprised between 1 and 20 μm. Preferential materials for the electrically conductive filler are carbon materials, such as carbon black, or graphene, or carbon nano-tubes, or mixtures thereof.

HDPE and POM are preferentially in relative percentages comprised between 45% and 55% of their sum in weight. Preferentially, the electrically conductive filler is confined either totally or to a large extent in the HDPE, in a weight percentage comprised between 10% and 45%, preferably between 16% and 30%, of the sum of the weight of the HDPE and the weight of the electrically conductive filler. For this purpose, the HDPE and the electrically conductive filler can be mixed together, in particular via extrusion, before subsequent mixing with the POM, which also in this case can be carried out preferentially via extrusion.

The high melting point of POM makes it possible to keep the two HDPE and POM phases better separated, thus reducing the possibility of migration of the electrically conductive filler in the POM (contributing to this effect is the fact that the filler is preferentially previously mixed with just the HDPE). The higher melting point of POM as compared to other known polymers likewise enables a more stable final structure to be obtained: the PTC effect of the composite material limits self-heating to a maximum temperature of approximately 120° C. POM moreover presents a high crystallinity, roughly comprised between 70% and 80%: this means that, in the preferential co-continuous composite proposed, it is less likely for there to occur migration of filler from the HDPE to the POM, thereby preventing loss of performance of the PTC-effect material, for example due to heating and passage of electric current. The higher crystallinity of POM also renders the composite particularly resistant from the chemical standpoint and bestows high stability thereon. On the other hand, the crystallinity of HDPE is typically comprised between 60% and 90%: in this way, a high concentration of the conductive filler in the amorphous domains is obtained, with corresponding high electrical conductivity.

The heating bodies 20₃ of the semi-finished product 20a are at a distance from one another in the direction of length L and generally extend in a direction transverse thereto, for example substantially orthogonal: in this way, at least in two opposite lateral end regions, here having regards to the width direction W, the material 20₄ of each body 20₃ can be electrically and mechanically connected to the two connection bodies 20₂. In various embodiments, such as the one represented, the bodies 20₃ have a prismatic shape, preferably a substantially parallelepipedal shape, but this does not constitute an essential characteristic of the invention. As seen above, in various embodiments, the width of the connection bodies 20₂, or the respective longitudinal elements, is a reduced fraction of the width of the opposite major faces of the heating bodies 20₃; hence, if need be, both the connection bodies 20₂ can also be associated to one and the same major face of the heating bodies, set at a distance from one another in the direction of width W, or substantially parallel and laying substantially according to one and the same plane.

In various embodiments, each of the two connection bodies 20₂ comprises respective electrical- and mechanical-connection parts, some of which are designated by 20₅, where associated to each heating body 20₃ are at least one first part 20₅, belonging to one connection body 20₂, and one second part 20₅, belonging to the other connection body 20₂. The aforesaid first and second parts 20₅ are preferably each associated at an aforesaid lateral end region of the body 20₃, here at the two opposite major faces thereof.

Preferentially, the connection parts 20₅ include a mesh structure. In various embodiments, such as the one exemplified in FIGS. 7 and 8, each of the two connection bodies 20₂ is entirely made of a single piece having a mesh structure, for example an electrically conductive fabric or a metal netting. However, in other embodiments (some of which are exemplified hereinafter), each of the two connection bodies 20₂ is made up of a number of parts, which comprise at least one first longitudinal element that extends in the direction of length L of the structure 20a and a plurality of second elements that extend in a transverse direction with respect to the first element, with the aforesaid second elements that each provide a respective mesh structure, i.e., an aforesaid electrical- and mechanical-connection part 20₅. In these embodiments, the first element that extends in the direction of length L does not necessarily have to have a mesh structure; by the way, its reduced width, which is only a fraction of the width of the heating bodies, eases in any case the capability of bending or deforming of the semi-finished product, as well as its cutting into a plurality of sections or lengths.

In various preferential embodiments, the mesh structure of the parts 20₅ is embedded or englobed at least partially in the corresponding heating body 20₃, i.e., in the resistive polymeric material 20₄, at the corresponding end region.

At least partial embedding of the mesh structure may be obtained by getting, via mechanical pressure and/or heating (preferably, heating such as to soften or melt at least superficially the resistive material), the structure itself to penetrate into the corresponding heating body 20₃ at a face of the latter, or else by overmoulding at least part of the resistive material of the heating body 20₃ on the mesh structure, i.e., on the corresponding electrical- and mechanical-connection part 20₅. The operation of embedding is made easier by the reduced width of the bodies 20₂, or in any case by the fact that each embedded part defines an area that, when see in a plan view, is equal to a limited faction of the area of the corresponding major face of the corresponding heating body 20₃. Preferably the embedding operation does not imply bending or curving of the connection bodies, that hence maintains preferably their substantially planar configuration.

It is to be noted that in the figures the mesh structure of the connection parts 20₅ is represented practically entirely in view, for reasons of greater clarity. However, preferentially, this structure is at least partially made to penetrate into the material 20₄ of the respective heating body 20₃, preferably in such a way that the mesh openings defined between the various meshes of the structure will be occupied by part of the material 20₄. On the other hand, it is also possible to embed practically completely a portion of the mesh structure of a connection part 20₅ into the material 20₄ of a heating body 20₃, in particular when the heating body is overmoulded on the corresponding connection parts 20₅.

It is preferable for the connection parts 20₅, or their mesh structures, to extend substantially parallel to a major face of the corresponding heating body 20₃. This ensures a good uniformity and a high intensity of the electric supply current between the connection bodies 20₂, which, as will be seen, are exploited for electrically supplying in parallel the various heating bodies 20₃. For this purpose, preferentially, the connection parts 20₅ hence extend in a direction of length L and in a direction of width W and are preferably substantially two-dimensional, i.e., of minimal thickness, substantially like a sheet or web structure; as said, their width is is fraction of the width of the bodies 20₃.

In various preferred embodiments, the mesh structure is constituted by a weave made at least in part of threads or wires of electrically conductive material, preferably metal material. Preferred metals may, for example, be selected from among stainless steel, copper, aluminium, brass, bronze, nickel-chromium-based alloys, or iron-chromium-based alloys. The electrically conductive fabric may be obtained via interweaving or criss-crossing of threads or wires using any known technique.

Preferentially, the threads that provide the electrically conductive fabric have a small nominal diameter (i.e., before being woven), roughly comprised between 0.2 mm and 0.02 mm. The mesh opening of the weave, i.e., the space between two adjacent and parallel threads of the structure, is preferably comprised between 1 mm and 0.05 mm. As already mentioned, on the other hand, the mesh structure could be obtained also by processing an electrically conductive body; for example, a mesh or net structure suitable for the application may be obtained by making through incisions (staggered cuts) in a length of metal strap, which is then deformed or stretched until openings or voids are obtained, for example having a substantially rhombus- or square-shape.

The fact that the mesh structure is at least partially embedded in the resistive material 20₄ prevents the risks of separation or detachment of the connection parts 20₅ from the corresponding heating body 20₃ and, notwithstanding this, enables possible deformation of the material 20₄ and/or of the mesh structure due to the heating and cooling cycles. The fact that the mesh structure is in any case relatively dense and extensive ensures a considerable current distribution and intensity.

The peripheral profile of the mesh structure that forms a connection body 20₂ may be easily obtained, for example, via elementary operations of cutting or dinking of a sheet or web of electrically conductive fabric or netting, or else the peripheral profile may be obtained via the aforesaid weaving processes. As will be seen, the aforesaid peripheral profile does not necessarily have to be quadrangular, as exemplified so far in the figures.

In the case illustrated in FIG. 7, the connection bodies 20₂ are each formed by a web with mesh structure, for example an electrically conductive fabric, with the electrical- and mechanical-connection parts 20₅ of one connection body 20₂ that are coupled to one major face of the heating bodies 20₃, and with the electrical- and mechanical-connection parts 20₅ of the other connection body 20₂ that are coupled to the opposite major face of the heating bodies 20₃. This arrangement is not on the other hand imperative. As has been said, the parts 20₅ may be substantially slotted or force-fitted into the heating bodies 20₃, i.e., via pressure and/or heating, on one face thereof, namely by getting the mesh structure to penetrate into the bodies 20₃. In embodiments of this sort, the bodies 20₃ may be obtained via operations of blanking or dinking starting from a starting sheet or web of the PTC-effect polymer, or else the bodies 20₃ may be injection-moulded.

In various embodiments, using suitable equipment, the areas of the bodies 20₂ corresponding to the connection parts 20₅ are pressed or pushed forcefully, after prior possible heating, on the aforesaid face of each body 20₃, causing penetration therein of the corresponding portions of the mesh structure. For this purpose, in preferential embodiments, the manufacturing equipment used is configured for heating the bodies 20₃ in order to cause a modest softening thereof that facilitates penetration of the PTC-effect polymeric material 20₄ into the openings of the mesh structures corresponding to the parts 20₅. Then, in particular after cooling of the bodies 20₃ (if heating thereof is envisaged), the pressure or thrust is interrupted, and the semi-finished product thus obtained can be removed from the equipment. This operation is made easier by the reduced width of the connection parts 20₅, or of the corresponding bodies 20₂.

The equipment used for the aforesaid purpose may be of any known conception, provided that it performs the functions described above. For instance, the equipment could be configured like a press, with a stationary element defining a plurality of seats for positioning of the bodies 20₃ and 20₂, with the bodies 20₂ locally set on top of the bodies 20₃, and a moving element that is designed to exert the necessary mechanical pressure on the bodies 20₂ at the parts 20₅. In such a case, the stationary element could also be configured for heating the heating bodies 20₃, as mentioned above. In addition or as an alternative, the equipment may be configured for heating the connection bodies 20₂.

According to other embodiments, the equipment could also be configured as a continuous-production machine, for example, one in which the two bodies 20₂ are supplied, starting from respective rolls or folded webs, at input to a workstation where the bodies 20₃ are loaded individually in order to be heated and then pressed against the bodies 20₂. At output from the aforesaid workstation, a substantially web-like heater semi-finished product is obtained, which can then be rolled up or else folded on itself, for the purpose of storage.

As has been said, the heating bodies 20₃ can also be configured as bodies overmoulded on the connection bodies 20₂, especially at the corresponding parts 20₅. In embodiments of this sort, for example, the two bodies 20₂ are inserted in a mould so that their areas that are to obtain the connection parts 20₅ are located in positions corresponding to the impressions that are to define the bodies 20₃. The PTC-effect polymeric material 20₄, in the molten state, is then injected into the mould so that the bodies 20₃ thus formed enclose within them the respective parts 20₅ of the bodies 20₂. Moulding of the bodies 20₃ may be provided in such a way that the meshes of the parts 20₅ will be completely embedded in the material 20₄, or else so that the meshes of the parts 20₅ will be partially exposed.

The various heating bodies 20₂ of a heater 20 may be electrically supplied by applying an electrical potential difference between the at least two connection bodies 20₂, for example by connecting a respective supply conductor directly to one of the longitudinal ends of the aforesaid bodies 20₂, for example the conductors 22 and 23 referred to previously.

In various embodiments, each of the connection bodies 20₂ is entirely formed by a single piece or element with mesh structure, for example a strip of electrically conductive fabric or of metal netting. This does not, however, constitute an essential characteristic in so far as each body 20₂ could be formed by assembling a number of parts together.

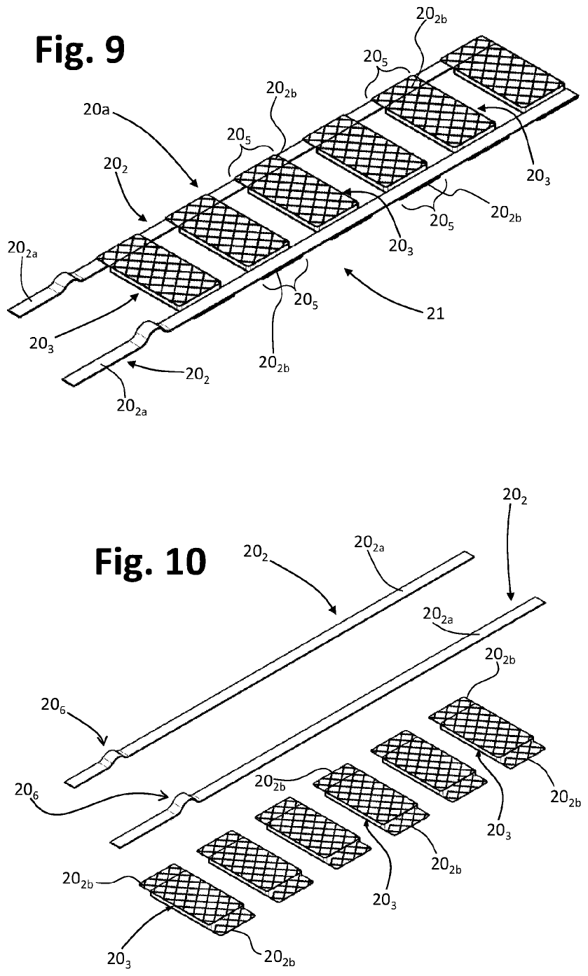

For instance, FIGS. 9 and 10 illustrate the case of a heater 21 in which each of the two corresponding connection bodies 20₂ is made up of a number of parts, comprising at least one first element 20₂ₐ that extends longitudinally in the direction of length L of the structure 20a, and a plurality of second elements 20_{2b} that extend in a direction transverse to the first element 20₂ₐ and that provide the connection parts 20₅. At least the second elements 20_{2b} each comprise a respective mesh structure, having a first portion that is at least partially embedded or englobed in the polymer-based material of a corresponding heating body 203, and a second portion that is instead fixed, in electrical and mechanical contact, to the first element 202a, preferably at least in part overlying the first element 202a.

Hence, in the example of FIGS. 9 and 10, two elements 20_{2b} with mesh structure basically provide two electrical terminals for each body 20₃. In this case, each body 20₃ may thus be overmoulded on the corresponding elements 20_{2b}, or else the two elements 20_{2b} may be made to penetrate into the corresponding body 20₃, according to what has been described previously, preferably so that a portion of each part 20_{2b} will in any case project on the outside of the body 20₃, for the purposes of connection to the respective longitudinal element 20₂ₐ, for example via welding, preferably welding without the use of added material. In various preferential embodiments, welding between the two parts 20₂ₐ and 20_{2b} in question is carried out by resistance welding, i.e., a pressure autogenous welding method in which the material is heated by electrical resistance.

Overmoulding of the bodies 20₃ on the corresponding elements 20_{2b} may be obtained in a number of steps and/or with a number of materials, or else the two elements 20_{2b} can be bonded to the corresponding body 20₃, in particular via an electrically conductive bonding agent that is preferably also thermally conductive. Also in this case, it is preferable for the meshed parts 20_{2b} of one connection body 20₂ to be coupled to one major face of the heating bodies 20₃, and the meshed parts 20_{2b} of the other connection body 20₂ to be coupled to the opposite major face of the heating bodies 20₃, with the parts 20_{2b} that extend substantially in a direction parallel to the respective major face of the corresponding heating body 20₃. In various embodiments, such as the one exemplified, the meshed structure represented by the parts 20_{2b} has an area at least corresponding to that of a major face of the corresponding heating body 20₃. In the example represented, the area of the parts 20_{2b} is larger in so far as it includes a portion that projects laterally from the major face of the body 20₃ for connection to a longitudinal part 20₂ₐ. In other embodiments, this projecting portion could, however, be omitted, for example when the longitudinal parts 20₂ₐ are in a position set both on top of the parts 20_{2b} and on top of the bodies 20₃.

It will be appreciated that, in embodiments of the type described with reference to FIGS. 19 and 10, or more in general in embodiments where the connection bodies 20₂ are made up of a number of assembled parts, the corresponding longitudinal elements—of the type designated previously by 20₂ₐ—do not necessarily have to have a mesh structure: instead, they may have a full structure, for example formed by a metal strip or strap, which is preferably flexible or deformable, possibly deformable even in a plastic way. It will likewise be appreciated that in such cases the longitudinal elements 20₂ₐ do not necessarily have to have a flat shape or web shape: for example, they may be obtained from threadlike elements, for instance having a substantially circular section.

The connection bodies 20₂ may also be formed entirely by a mesh structure, but have a complex peripheral profile, for example substantially comb-shaped, so as to define respective electrical- and mechanical-connection parts that project in a transverse direction.

At least two heating bodies 20₃ of at least two respective structures 20a of heaters 20, 21 could be connected to one and the same connection body 20₂; or they could have an electrical connection (i.e., an electrode) in common.

The distribution of the electric power and heating capacity of a semi-finished product 1 according to the invention, or else of a device that uses it, can be easily varied in the production step in various ways, for example by means of variation of the dimension of length of the heaters 20, 21 and/or variation of the shape and/or of the length of the heating bodies 20₃ (the term “length” is here to be understood as referring to the dimension of length L of the structure 2a of the heaters 20, 21).

On the other hand, one and the same heater 20, 21 may include an alternation of bodies 20₃, which have different lengths. In addition or alternatively, the distribution of the electric power and of the heating capacity of a heater 20, 21 may be obtained in the production stage by variation of the distance between the corresponding heating bodies 20₃ in the direction of length L. Another possibility still for distributing the electric power and heating capacity of a semi-finished product 1 (i.e., of an electric heater device that integrates it) that uses a number of heaters 20, 21 in a configuration where they are set alongside one another is to vary the distance between the heaters themselves.

In general, and with reference to FIGS. 7-8 and 9-10, the power density at the electrical- and mechanical-connection parts 20₅ depends upon the specific modalities of coupling between the connection bodies 20₂ and the heating bodies 20₃. For instance, connection configurations of the type described with reference to FIGS. 9 and 10, such as configurations with an electric current that substantially circulates in the direction of the thickness (dimension with reference T, FIG. 7) of the heating bodies 20₃, enable power densities to be reached that are decidedly higher as compared to configurations of the type described with reference to FIGS. 7 and 8, such as configurations with an electric current that substantially circulates in the direction of the width W of the heating bodies 3.

On the above basis, according to possible preferential embodiments of the invention, it is possible to integrate in a semi-finished product 1 heaters distinguished by different versions of the connection parts 20₅, for example first heaters 20 with parts 20₅ according to FIGS. 7 and 8 and second heaters 20 with parts 20₅ according to FIGS. 9 and 10; i.e., it is possible to integrate different versions of the connection parts 20₅ that are designed to get the electric current to circulate in the direction of thickness T and/or in the direction of width W: in this way, it is possible to differentiate the powers in the various areas of the semi-finished product, i.e., in the heater device that integrates it, for example to have high power values in some specific points and less high power values in other points.

Embodiments of this sort are, in fact, represented in FIGS. 3-6 and 11, where both heaters 20 with lower heat-emission power and heaters 21 with higher heat-emission power are used, in particular in configurations where they are set alongside one another in one or more lateral regions 5 or 6 (FIG. 1) of the semi-finished product 1. On the other hand, as has been said, also in the central region 4 of the semi-finished product a number of heaters 20 and/or 21 could be provided in a configuration where they are set alongside one another.

As mentioned previously, the mesh structure used in the heaters 20, 21 is preferably formed by the interweaving or criss-crossing of relatively thin elements or parts, for example threads or portions of a netting obtained from machining of a strap. The aforesaid elements or parts preferably have a diameter or other cross-sectional dimension comprised between 0.2 mm and 0.02 mm. This enables an efficient fixing of the mesh structures to the material 20₄ of the heating bodies 20₃, also thanks to their at least partial embedding in the aforesaid material, thus countering any risk of detachment between the parts in question. For instance, threads that have a diameter smaller than 0.1 mm are advantageous for enabling their forced penetration into the material 20₄, preferably by heating the latter, as explained previously, and this also in the case of small mesh openings, for example even smaller than 0.05 mm. Threads that have a diameter larger than 0.1 mm may, instead, prove more convenient to use when the material 20₄ is overmoulded and it is necessary to have available wider mesh openings to enable penetration of the material itself, for example mesh openings even larger than 1 mm (in general, in conductive woven fabrics that can be used for implementation of the invention, corresponding to threads of larger diameter are wider mesh openings).

In various embodiments, one or more heaters of the semi-finished product has/have respective connection bodies 20₂ that include a meshed structure of the type referred to, through which areas of the casing parts 10, 11 can be locally joined together. In other words, during joining of the two casing parts 10, 11, a part of the material of one part or both parts, or of an adhesive that is to join them together, can be made to penetrate into the meshed structure so that the two parts 10, 11 will weld or bond together. In this way, if need be, the two casing parts 10, 11 can be locally joined together also at the connection bodies 20₂. In this way, it is, for example, possible to seal a region 4, 5, or 6 with respect to another region 4, 5, or 6, or else within a region 4, 5, or 6a plurality of sealed chambers may be defined, for example to enable further reduction of the presence of air or to prevent any possible infiltration into an area of a region from extending to other areas or else to the entire heater.

With reference to the examples of FIGS. 7-8 and 9-10, i twill be appreciated that—since the connection bodies 20₂ or the longitudinal elements 20₂ₐ are of a smaller width than the heating bodies 20₃, and associated to opposite lateral ends thereof, (in particular spaced from each other or staggered in the respective intermediate parts)—the risk is avoided of short-circuit between said bodies 20₂ or elements 20₂ₐ, without the need to provide an insulating element therebetween. In the exemplified cases, the connection bodies 20₂ or the parts 20_{2b} are embedded or englobed at least partially at the two opposite major faces of the heating bodies 20₃. Also with this arrangement the connection bodies 20₂ or the longitudinal elements 20₂ₐ are substantially parallel and spaced from each other in the direction of width W, without a body or element being above the other body or element in the areas comprised between two heating bodies 20₃ (i.e., with a structure of the semi-finished product which is in any case distinguished by a succession of “voids”, each delimited by two successive heating bodies and the corresponding sections of body 20₂ or element 20₂ₐ that join said bodies 20₃).

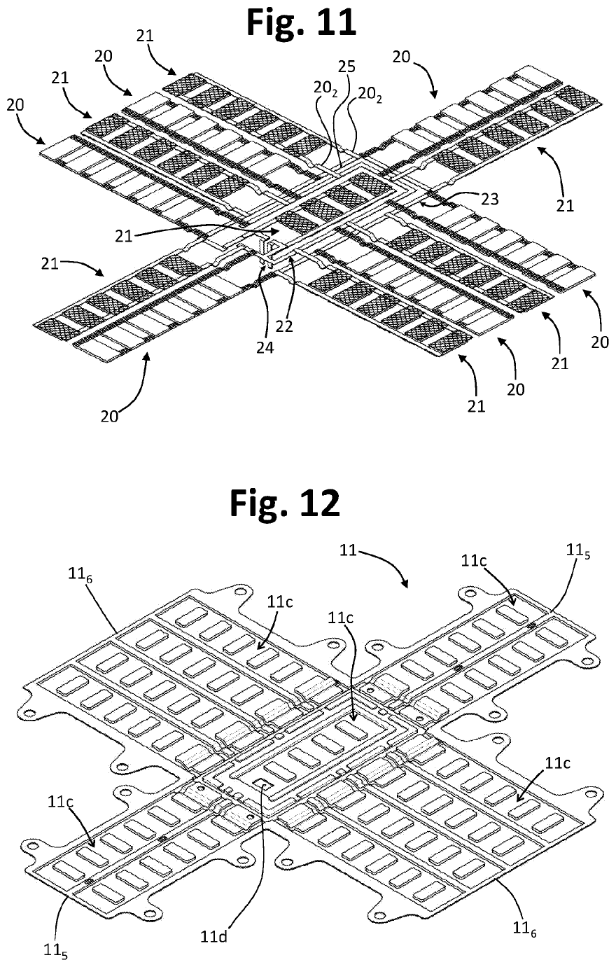

Visible in FIG. 11 are the electrical parts of a semi-finished product 1 of the type illustrated, for example, in FIG. 6, with one of the two connection bodies 20₂ of each heater 20, 21 that is connected to the conductor 22, and the other of the two connection bodies 20₂ of each heater 20, 21 that is connected to the conductor 23. In the example, the conductors 22, 23 define an approximately rectangular profile so that they can be arranged at the central region 4 of the semi-finished product 1 (see FIGS. 1 and 2), around a heater (here a heater 21).

In various examples of embodiment, the perimetral dimensions of the two conductors 22, 23 are different, i.e., they are preferably arranged substantially concentric, with the consequence that one of the two connection bodies 20₂ of the peripheral heaters must extend over the outer conductor 23 so that it can be connected to the inner conductor 22. In order to prevent any possible electrical contact between the aforesaid body 20₂ and the conductor 23, between at least some portions of these two components electrical-insulation means are hence preferably provided, which may be represented by an electrically insulating film or tape, of the type previously designated by 25 (alternatively, it is possible to use an insulating resin or a paint, or else a different insulating or dielectric element, such as a polymer or other material, for example a mica or other mineral material or a ceramic material or an oxide).

Is it is to be assumed that the insulator 25 used in the case of FIG. 11 does not have a quadrangular shape, as in FIG. 6, but has, instead, a shape corresponding to that of the conductor 23 and is directly applied on the latter, for example in the form of insulating film or of portions of insulating film.

Visible, instead, in FIG. 12 is the casing part 11, and in particular its face where the housing 11c, which is to receive the electrical parts of FIG. 11, i.e., the plurality of heaters 20, 21 and the plurality of conductors 22, 23, is defined. As has been said, the housing 11c has a shape that is at least in part complementary to that of the various elements 20-23 that are to be received, or a shape such as to define separation and/or positioning elements for the heaters 20, 21, in particular elements or walls in relief, in order to improve relative positioning between the parts in question.

In FIG. 12, moreover, designated by 11d is a passage of the casing part 11, through which the aforementioned projecting portions of the connection terminals 24 are to extend; at said passage 11d, on the side of the casing part 11 opposite to the one visible in FIG. 12, the connector body 3 is then to be mounted (see FIG. 5).

It should also be noted how the connection bodies 20₂ of the heaters 20, 21 may be conveniently shaped for adapting at least partially to the configuration of the casing body part 10 and/or 11 that receives them, in particular thanks to the flexibility or deformability of at least some portions of these bodies, at least in their direction of length L. There may also be envisaged connection bodies 20₂ provided with areas for dimensional compensation, in particular in the longitudinal direction of the heaters 20, 21.

It should be noted to this purpose that, in various embodiments, the connection bodies 20₂ of the heaters 20, 21 that are to be arranged at the peripheral regions 5, 6 of the semi-finished product 1 extend in a direction transverse to the folding areas 1a (FIGS. 1-2). For this reason, and with reference to FIGS. 8 and 10, these bodies 20₂ may be shaped so as to present curved portions 20₆ that are to couple to the profile of the corresponding folding areas 10a and 11a (FIG. 3) of the casing parts 10 and 11 (see also FIG. 3), and hence facilitate the subsequent step of folding at an angle of the semi-finished product, preferably preventing mechanical stresses from arising in the connection bodies 20₂ during the folding steps.

In various preferential embodiments, the casing parts 10 and 11 are welded together, for example via vibration welding, while a tool (for example, a sonotrode) compresses them together locally, in particular at least in the areas around the heating bodies 20₃ and/or the connection bodies 20₂ of the various heaters 20, 21, thus preventing or reducing the presence of air inside the casing body 2 of the semi-finished product 1. In this way, the risk of possible operating faults of the heater device subsequently obtained is prevented or reduced: the presence of a large amount of air within the casing 2 could in fact cause significant expansion during the operating steps of heating of the heater device.

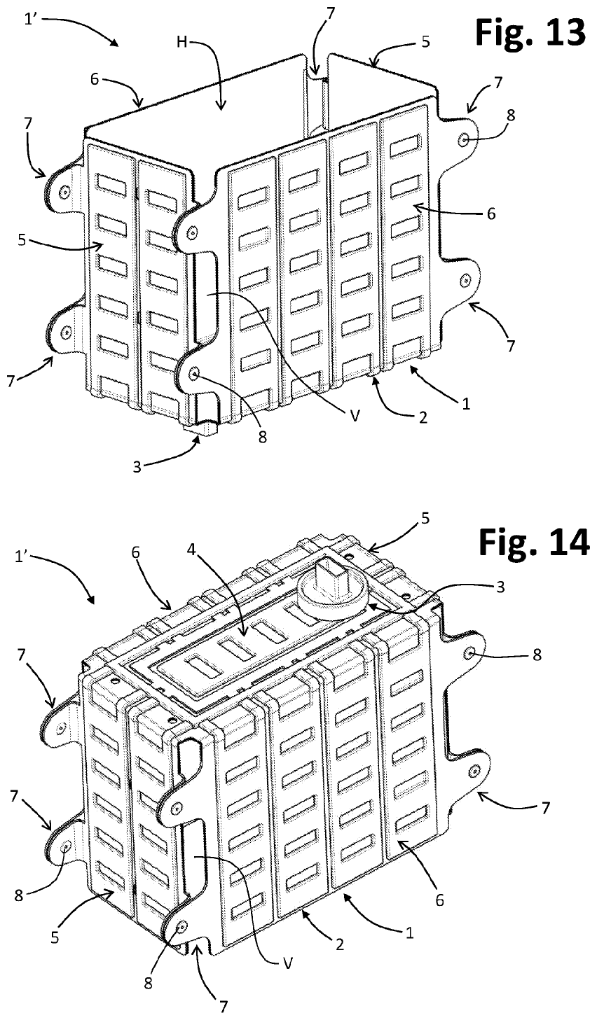

FIGS. 13-14 exemplify an electric heater device according to possible embodiments of the invention, designated as a whole by 1′, which may, for example, belong to a system for heating a flow of air or for heating a liquid that is contained in a tank or that flows in a duct.

The device 1′ is obtained starting from a semi-finished product of a heater device 1 of the type illustrated in FIGS. 1-2, which—as has been seen—encloses at least partially a plurality of heaters (20, 21), which are, in turn, preferably formed by lengths of one or more corresponding heater semi-finished products. The device 1′ is substantially obtained by folding substantially orthogonally the peripheral regions 5, 6 of the semi-finished product 1 with respect to the central region 4, at the folding areas (1a, FIGS. 1-2), so as to obtain a substantially box-like or three-dimensional body, which, in the example, substantially defines a cavity or a hollow volume designated by H. Hence, following upon this folding operation, the regions 4 and 5-6 of the semi-finished product 1 come to constitute the bottom wall and the lateral walls, respectively, of the device 1′, which are substantially orthogonal to each other. It will be appreciated that the regions 4, 5 and 6 are as a whole stiffer than the areas 1a, both by virtue of the shaping determined by the housing 11c and by virtue of the presence of the heaters 20, 21.

In embodiments of this type, the various contiguous regions or walls 5, 6 are at least locally rendered fixed with respect to one another after folding. In the example illustrated in FIGS. 13-14, shaped connection or joining areas, designated by 7, are provided for this purpose, obtained by exploiting the appendages or brackets 5a and 6a of FIG. 1.

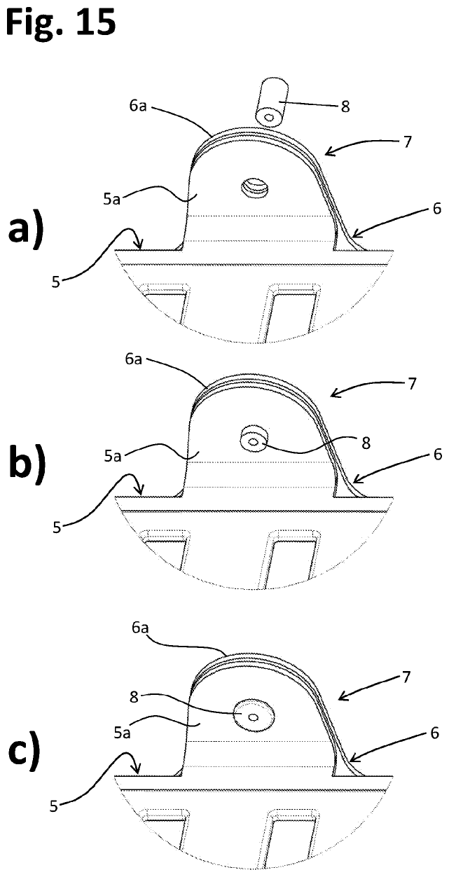

A possible modality for obtaining the joining areas 7 is illustrated in FIG. 15, from which it emerges how, in each area 7, the appendage 5a of a region or wall 5 is set on top of the appendage 6a of a region or wall 6. It should be noted that, in the case exemplified, for the purposes of superposition between the appendages 5a and 6a, at least the appendage 5a is folded relative to the corresponding region or wall 5 in order to assume a position generally parallel to the appendage 6a.

Following upon mutual superposition of the appendages 5a, 6a, as in part a) of FIG. 15, the latter are rendered fixed with respect to one another. Mutual fixing may be obtained via gluing, or else welding, or else by providing further mechanical fixing members. In the case exemplified, the appendages 5a, 6a are each provided with a respective through hole (not indicated) suitable for receiving an additional fixing member 8, here represented by a pin or stud or rivet. In the example, the aforesaid pin 8 is inserted into the holes arranged coaxially of the two appendages 5a, 6a, as may be seen in part b) of FIG. 15, and then the pin 8 is subjected to deformation, for example via upsetting, at its axial ends, as may be seen in part c) of FIG. 15, so as to withhold the appendages 5a and 6a adjacent to one another. The pins 8 may also be made of plastic material, for example the same material used for obtaining at least one of the casing parts 10, 11, in which case its ends may be subjected to hot upsetting (the pin 8 could have a widened head or end, i.e., be in the form of a rivet, in which case it will be sufficient to deform just the opposite end).

As may be noted from FIGS. 13 and 14, thanks to the joining areas 7, it is possible to ensure maintenance of the three-dimensional shape of the heater device 2. As has been mentioned previously, the folding areas 1a of the semi-finished product 1 (FIGS. 1-2) may substantially perform functions of elastic hinge in order to enable folding of the peripheral regions/walls 5, 6 with respect to the central region/wall 4. On the other hand, this is not strictly indispensable in so far as folding may be carried out—for example, hot—without the areas 1a functioning as elastic hinges.

Folding may possibly be carried out even without envisaging in the areas 1a the aforementioned concavities or grooves or reductions in thickness or incisions. Even in the absence thereof, in fact, the semi-finished product 1 according to the invention is in any case prearranged for enabling folding of at least one region or wall thereof with respect to another region or wall thereof. In the absence of the aforementioned concavities or grooves or reductions in thickness or incisions, prearrangement of the semi-finished product in any case comprises an appropriate layout and/or configuration of the heaters 20, 21, the electrical conductors 22, 23, and the housing 11c for the heaters and conductors, such as not to hinder—but rather favour—the subsequent step of folding of the semi-finished product (i.e., such as to identify, in any case, areas in the casing body 2 designed for folding, preferably areas with lower stiffness than the ones where the heaters are located).

The folding areas are preferably areas of the semi-finished product 1 and/or of the casing parts 10, 11 where only electrical conductors 22, 23 and/or connection bodies 20₂, 20₂ₐ are present, i.e., areas without heating bodies 20₃ or insulating elements between superimposed electrical parts, such as the elements 25.

The hollow volume H defined by the device 1′ may be open, not only at its part opposite to its central region/wall 4, but also at its lateral regions/walls 5, 6 and/or in corner areas of the structure. For instance, one or more lateral walls 5, 6 may be provided with through openings (some openings of the corresponding semi-finished product 1 are visible, for example, in FIG. 2, in the regions 5), or else the conformation of edges of the regions/walls 5, 6 and/or of the corresponding connections 7 may be such as to enable the presence of angular ports or passages, some of which are designated by V in FIGS. 13 and 14. The presence of the aforementioned openings or ports may prove useful in various applications, for example, when it is desired to enable or favour circulation of a fluid (liquid or gas) through the heater device 1′.

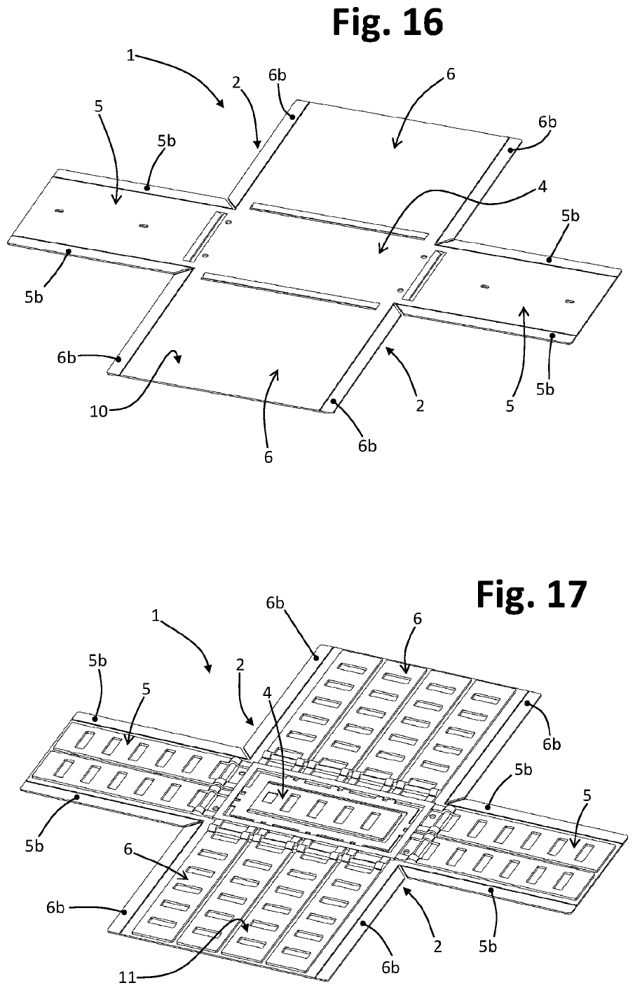

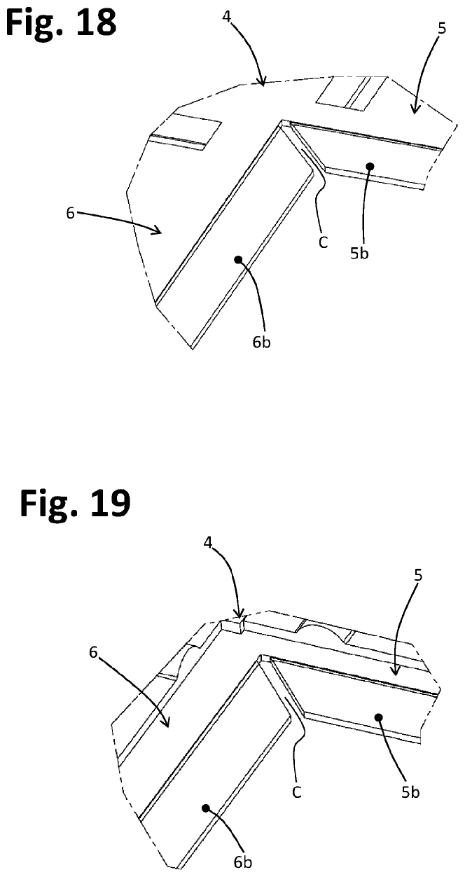

Illustrated schematically in FIGS. 16-17 is a semi-finished product 1 according to further possible embodiments of the invention. The semi-finished product 1 of these figures is built in a way substantially similar to that of FIGS. 1-2, but in this case, for the purposes of mutual fixing or coupling between the peripheral regions 5, 6, the latter are not provided with appendages or brackets 5a, 6a to obtain localized connections, but are provided with longitudinal joining edges 5b, 6b in order to obtain a single continuous connection. Details of two of the above contiguous edges 5b, 6b are visible in FIGS. 18 and 19.

The edges 5b, 6b may each be defined by respective portions of the two casing parts 10, 11 of the body 2, or else be defined by just one of them, for example by the part 11. In any case, a sit can be seen, the coupling or joining elements here represented by the brackets 5b e 6b are preferably defined by portions of the casing body that have a reduced thickness with respect to those in which the electric heaters 20 and/or 21 are integrated. Irrespective of the type of embodiment, the joining edges 5b, 6b preferentially extend substantially for the entire length of the longitudinal sides of the regions 5, 6. As may be noted in FIGS. 18-19, preferentially at their lower end (i.e., in a position substantially corresponding to the central region 4), contiguous edges 5b and 6b are separated from one another by an intermediate cut or interruption C, aimed at enabling subsequent folding of the edges themselves.

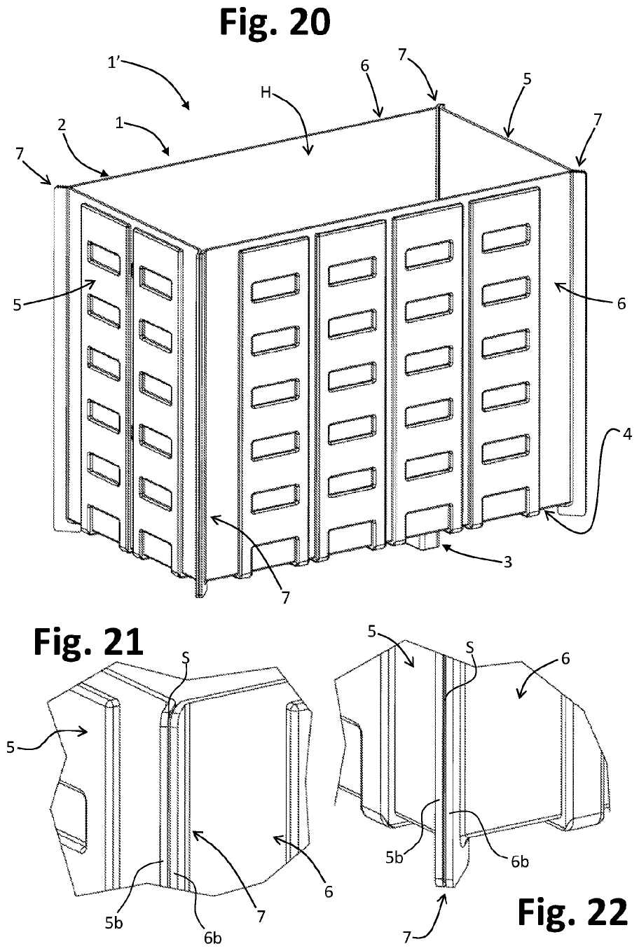

The longitudinal edges 5b and 6b are able to bend elastically so that—following upon folding of the peripheral regions 5, 6—an edge 5b may be set up against an edge 6b in order to obtain connection or joining areas 7 between the various regions 5, 6, as may be seen in FIG. 20, which represents a substantially three-dimensional heater device 1′ that can be obtained starting from a substantially planar, or plate-like, or two-dimensional semi-finished product of the type illustrated in FIGS. 16-17. As may be noted also from the details of FIGS. 21-22, the edges 5b and 6b may themselves be folded with respect to the corresponding regions/walls 5 and 6 in order to be substantially parallel to one another. In the case of FIGS. 20-22, in order to render the edges 5b and 6b fixed with respect to one another, between them there can be set an adhesive material designated by S in FIGS. 21-22, which also performs the function of seal. Alternatively, the edges 5b and 6b may be mechanically coupled together via appropriate hooks or via means 8 of the type described previously, with interposition of a sealing element or gasket, for example made of elastomer.

It will be appreciated that, in this case, coupling along the edges 5b and 6b may be entirely fluid tight so that the internal volume H of the heater device 1′ is also able to contain a liquid (if this is required, the lateral walls of the device 1′ will obviously be without through openings).

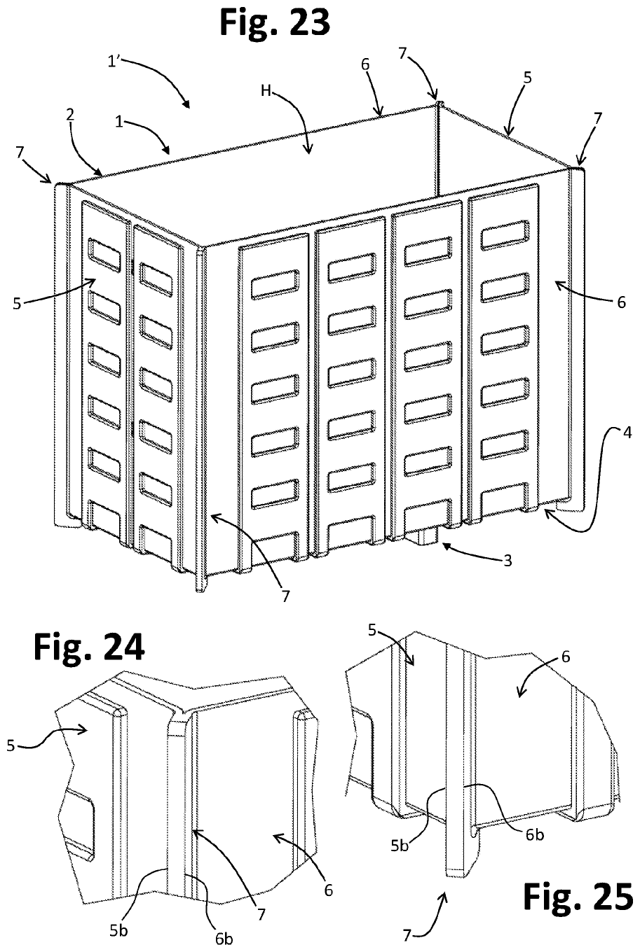

FIGS. 23-25 illustrate, instead, a device 1′ of a conception similar to that of FIGS. 20-22 (i.e., obtained starting from a semi-finished product 1 of the type illustrated in FIGS. 16-17), but the joining edges 5b, 6b of which are joined together via welding or partial remelting of their constituent material in order to guarantee also in this case a fluid-tight join. For this purpose, a semi-finished product 1 of the type illustrated in FIGS. 16-17 can be folded or shaped so as to obtain a shape substantially similar to that of the device 1′ of FIGS. 20-22, i.e., with the joining edges 5b, 6b set alongside one another, subsequently carrying out mutual welding of the above edges, preferably a welding performed while also a mutual compression of the joining edges 5b, 6b is exerted, in particular via purposely provided welding equipment. For this purpose, there may be envisaged equipment used for the purposes of vibration or ultrasound welding, or else equipment for welding of the hot-remelting type, such as welding of the hot-blade or laser-welding type or of some other type suited for the purpose. To this end, the welding equipment, such as the sonotrode of vibration- or ultrasound-welding equipment or else a heated plate of remelt- or hot-welding equipment, could be appropriately shaped, for example with a shape at least in part complementary to the one that the edges 5b, 6b are to assume.

It should be noted that, in possible variant embodiments not exemplified, between the edges 5b and 6b there could be provided additional sealing means, such as a gasket, with the edges themselves joined together with additional fixing means (for example, an outer profile fitted on the edges, between which the gasket is set).

Illustrated in FIGS. 26-27 is a further semi-finished product 1 according to possible embodiments of the invention. In solutions of this type, the casing body 2 of the semi-finished product does not have a central region with respect to which peripheral regions are folded, but has, instead, a succession of first regions 5, 6 that are set alongside one another in a first direction and can be folded towards one another, and are, for example, to form the lateral walls of a heater device. Alongside at least one of these first regions (here a region 6), in a second direction, there may be set at least one second region 4, which, for example, is to form at least part of a bottom wall of the heater device.

Also in this case, preferentially, between the various first regions 5, 6, folding areas 1a are defined, substantially of the type already previously referred to, and the two first regions 5, 6 at the ends of the succession are provided with respective longitudinal edges 5b and 6b. The first regions 5, 6 different from the one that is associated to the region 4 are also preferably provided with lower edges 5c, 6c, the function of which will be clarified hereinafter. The longitudinal edges 5b, 6b and the lower edges 5c, 6c of the first regions are preferentially defined through grooves or reductions in thickness 5d, 6d of the various regions 5, 6 concerned. Also defined between the region 4 and the corresponding region 6 is such a groove or reduction in thickness, designated by 6e in FIGS. 26 and 27. From the details of FIGS. 28 and 29 it may be noted how, preferentially, between the lower edges 5c, 6c of the first regions 5, 6, intermediate interruptions C are provided, substantially in the folding areas 1a, for the purposes clarified hereinafter.

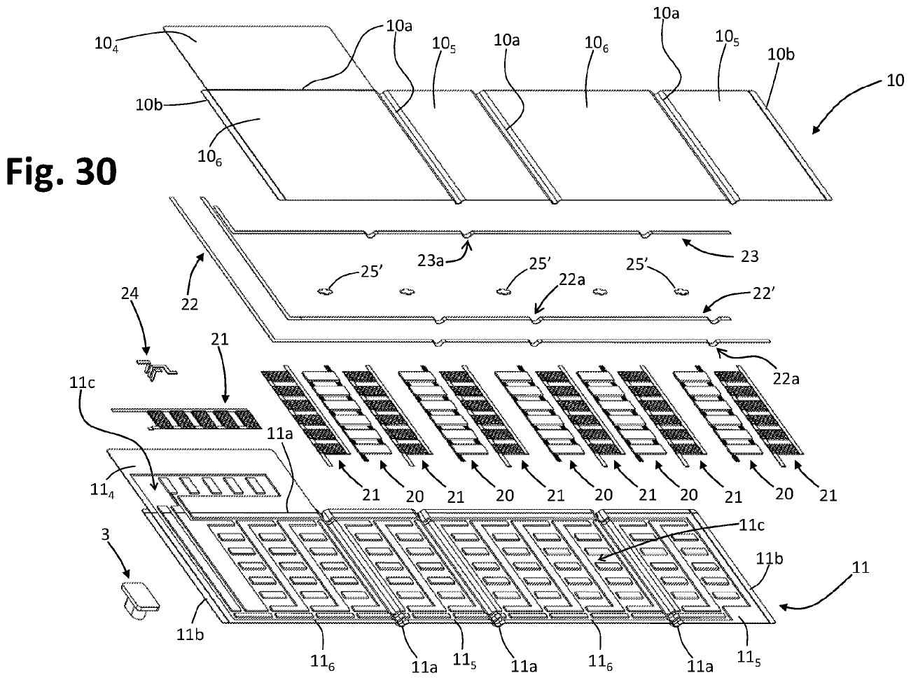

Represented in exploded view in FIG. 30 is a semi-finished product of the type illustrated in FIGS. 26-27. Also in this case, the casing body of the semi-finished product comprises at least two casing parts 10 and 11, which preferentially have peripheral profiles that are substantially similar or corresponding to one another, and preferably substantially similar or corresponding to the final peripheral profile of the casing body 2 of the semi-finished product 1 (see FIGS. 26-27). In this perspective, in various embodiments, the parts 10 and 11 each have a succession of first regions, designated by 10₅, 10₆ and 11₅, 11₆, respectively, extending orthogonally from at least one of which (here a region 10₆ and 11₆) is a second region 10₄. Preferably, the aforesaid regions 10₄, 10₅, 10₆ and 11₅, 11₆, are relatively stiff. Preferentially, the casing parts 10 and 11 are provided with respective folding areas, designated by 10a and 11a, of the type already described previously, which, in the condition where the two casing parts 10 and 11 are coupled together, are set on top of one another to obtain the folding areas 1a of FIGS. 26-27.

Preferentially, provided on the outer side of the two first end regions 10₅, 10₆ and 11₅, 11₆ are respective longitudinal edges 10b, 11b. In the condition where the two casing parts 10 and 11 are coupled together, the corresponding appendages 10b and 11b are set on top of one another to obtain the edges 5b and 6b of FIGS. 26-27. The lower edges 5c, 6c of FIGS. 26-27 may be defined by just one of the two casing parts, for example the part 11.

Visible once again in FIG. 30 are the heaters of the semi-finished product, preferably but not necessarily of two different types, such as the types previously designated by 20 and 21 (they may, however, be of some other type and/or may have some other shape and/or may be combined together differently, for instance as described in the previous examples). The heaters are arranged in a configuration where they are set alongside one another at least in the first regions 5, 6, here with three heaters 20, 21 at the wider regions 6, and two heaters 20, 21 at the narrower regions 5. At least one heater—here of the type designated by 21—is set also at the second region 4. Also in the case exemplified in FIG. 30, the casing part 11 is shaped so as to define the housing 11c for the various heaters 20, 21 and the other electrical-connection parts 22-24.

In various embodiments, the semi-finished product and/or the corresponding heater device are/is prearranged so as to enable a diversified supply of the heaters, i.e., so as to enable supply of at least some heaters separately from other heaters. In the case exemplified in FIG. 30, three electrical conductors 22, 22′ and 23 are provided for this purpose.

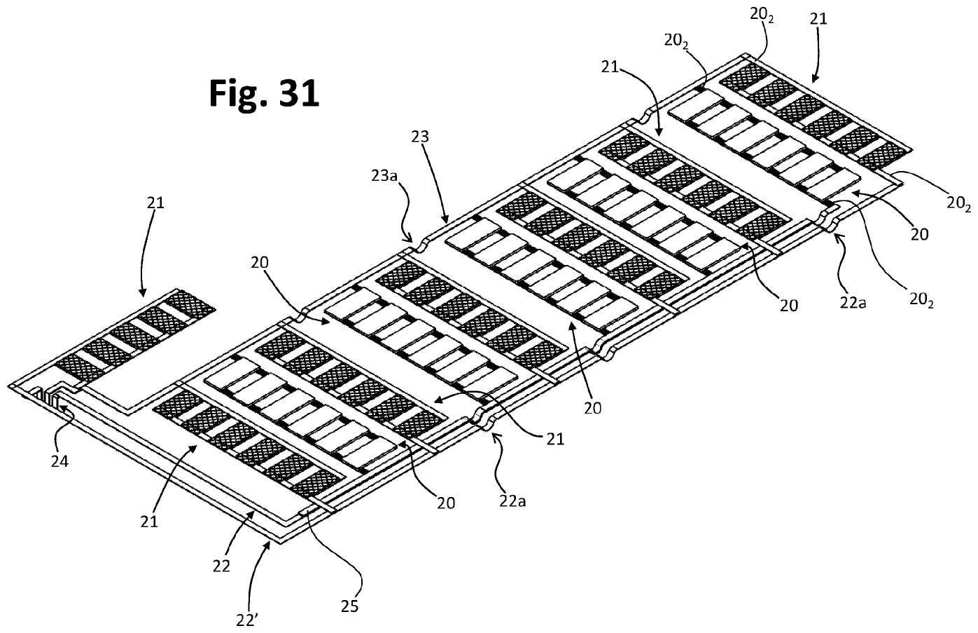

With reference also to FIG. 31 (and in particular to the two heaters 20 and 21 on the right-hand side of FIG. 31), a first connection body 20₂ of some heaters (here the heaters 20) is electrically connected to the conductor 22, whereas a first connection body 20₂ of the other remaining heaters (here the heaters 21) is connected to the conductor 22′. All the second connection bodies 20₂ of all the heaters 20, 21 are, instead, electrically connected to the conductor 23 (in other words, the heaters 20 are connected together in parallel between the conductors 22 and 23, whereas the heaters 21 are connected together in parallel between the conductors 22′ and 23).

In various embodiments, the semi-finished product or the corresponding heater device is provided with at least one conductor 23 that determines at least one electrical connection in common between the heaters 20, 21, preferably at least one common conductor 23 that connects at least two heaters 20 and 21, which are provided with respective conductors 22 and 22′.

In this case, three electrical terminals 24 are provided, each of which is connected to a respective conductor 22, 22′, and 23. Also in this case, a connector body 3 is provided, which is able to receive a portion of the three terminals 24 in order to provide an electrical connector.

It will be appreciated that, with a configuration of electrical connection of the type referred to, it is possible to supply separately different sets of heaters: in the example, in fact, the heaters 20 can be supplied by applying a difference of electrical potential between the conductors 22 and 23, whereas the heaters 21 can be supplied by applying a difference of electrical potential between the conductors 22′ and 23. As may be appreciated, in a heater that integrates a semi-finished product 1 distinguished by a similar type of electrical connection of the heaters, it is possible to control or vary the distribution of heat, for example first to provide an immediate heating thanks to first heaters with higher heat-emission power (such as the heaters 21), and then to maintain a sufficient degree of heating, but with lower electrical consumption, thanks to the second heaters with lower heat-emission power (such as the heaters 20), interrupting, instead, electrical supply to the first heaters. This configuration also enables variation of the power and/or distribution of the heating by supplying at different moments only some heaters 20, 21 and at other moments all the heaters 20, 21. This configuration moreover enables reduction of the peaks of electrical absorption by supplying the heaters 20, 21 at different times, for example by supplying first the heaters 20 and after a certain time also the heaters 21. In the case of electric heaters 20 of the PTC-effect type, i.e., with a resistance with positive temperature coefficient, these would absorb a high current in the first few seconds after application of the corresponding electric power supply, and then reduce considerably their own current absorption while they are heating up. When the absorption of the heaters 20 decreases, also the heaters 21, which could likewise be of a PTC type, could be supplied electrically and hence absorb a high electrical current only in the first few seconds after application of the electric power supply, and then reduce their electrical absorption while they are heating up, thus obtaining a total electrical absorption that is relatively low or in any case without high peaks.

Of course, with the configuration of electrical connection exemplified in the figures, even all the heaters of the semi-finished product could be of the same type. Also in the case of heaters of the same type, the possibility of supplying them separately and/or at different moments in any case enables the aforesaid variations of power and/or of distribution of the heating to be obtained, and/or enables limitation of the peaks of electric current absorption.

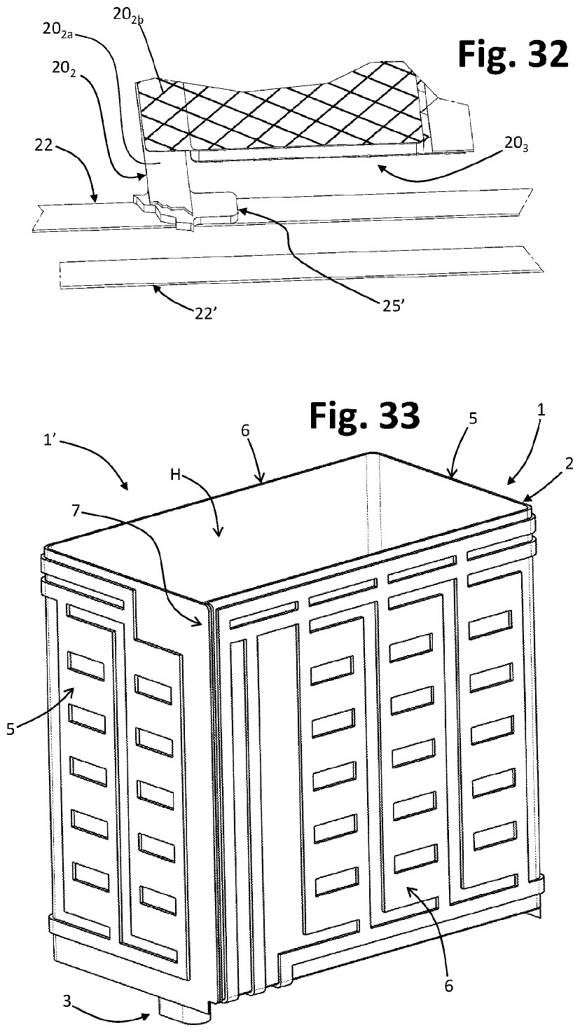

From FIG. 31 there may moreover be noted a possible implementation of an electrical insulation 25, represented only partially in the form of a film or coating, set above the conductor 22, for the purposes already referred to previously. On the other hand, instead of a continuous film or an insulation coating of the type designated by 25 in FIG. 31, a plurality of insulation elements of a discrete or localized type may be provided, some of which are designated by 25′ in FIG. 30, which can be set at areas of intersection between the conductor 22 and the connection bodies 20₂ of the heater bodies that are, instead, to be connected to the conductor 22′: the concept is clarified in the detail of FIG. 32, where one of the aforesaid discrete electrical-insulation elements 25′ is represented partially sectioned, set between a body 20₂ and the conductor 22 in order to prevent short-circuits between these elements.

In various embodiments, at least one of the casing parts (10, 11) is overmoulded on at least a portion of at least one of the electrical conductors (22, 22′, 23). In this configuration, the aforesaid electrical insulator (25, 25′) between the electrical conductors and/or the connection bodies (20₂) could also be constituted by at least one portion of the casing (2) or of at least one of its parts (10, 11).

Once again from FIGS. 30 and 31 it may be noted how in various embodiments the conductors 22, 22′, and 23 may be shaped so as to present curved portions 22a, 23a that are to couple to the profile of the corresponding folding areas 10a and 11a of the casing parts 10 and 11, and hence facilitate the subsequent step of folding of the semi-finished product, preferably preventing any possible mechanical stresses in the conductors 22, 22′, and 23 during the aforesaid folding steps.

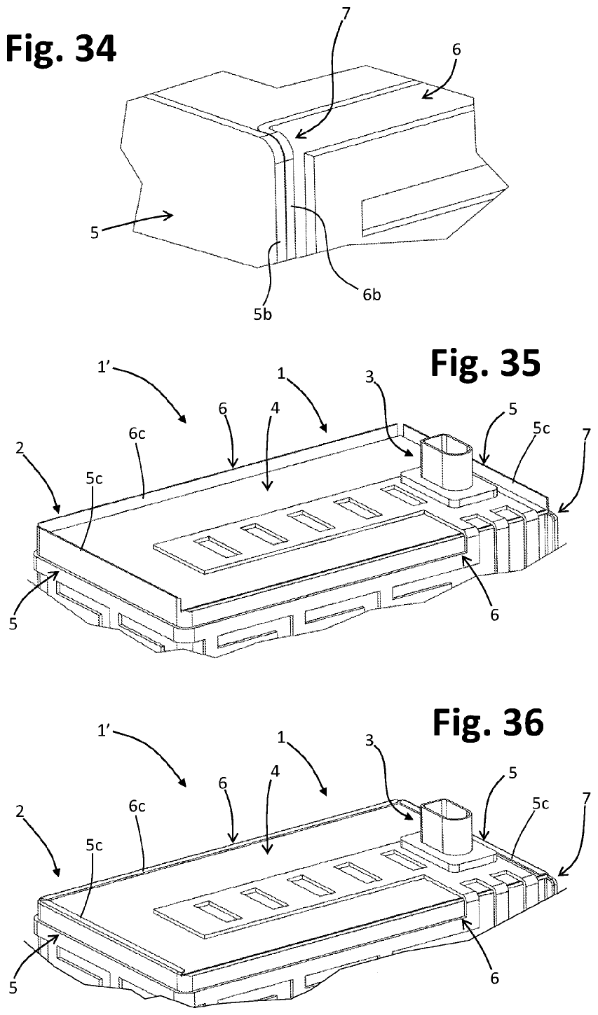

Visible in FIG. 33 is a heater device 1′ that can be obtained starting from a semi-finished product of the type illustrated in FIGS. 26-67. As may be appreciated, for this purpose, the first regions 5, 6 of the semi-finished product 1 are folded towards one another at the folding areas 1a of FIGS. 26-27 so as to obtain the lateral walls of the heater device 1′, which delimit the hollow volume H. This volume H can then be closed at the bottom, by folding, in turn, the second region 4 towards the lower edge of the first regions 5, 6, exploiting the presence of the recess 6e (FIGS. 26-27). The longitudinal end edges 5b and 6b of FIGS. 26 and 27 can then be slightly folded with respect to the corresponding regions 5, 6 (thanks to the corresponding recesses 5d, 6d) so that they can be set up against one another and rendered fixed with respect to one another, for example via an adhesive or via welding (or some other mechanical fixing with interposition of a gasket or sealing element, for example made of elastomer), to obtain a respective joining area 7, as exemplified in the detail of FIG. 34.

Following upon folding of the regions 4, 5, and 6, the lower part of the device is substantially as represented in the detail of FIG. 35. The lower edges 5c and 6c of the regions/walls 5 and 6 where these edges are provided are still in a substantially splayed-out configuration, and are then folded on the outer side of the region/wall 4, as illustrated in FIG. 36, and fixed thereto, for example via gluing or welding (or some other mechanical fixing with interposition of a gasket or sealing element, for example made of elastomer). The edges 5c, 6c in question may be conveniently brought into the condition illustrated in FIG. 36, exploiting the presence of the interruptions C and of the recesses 5c, 6c of FIGS. 28-29.

From what has been described previously it emerges how, in various embodiments, the semi-finished product (1) may be provided with a first shape or configuration, which is at least in part relatively stiff, and may subsequently be made to assume a second configuration or shape (1′), which is at least in part relatively stiff, preferably via appropriate folding and/or with the aid of predefined folding areas.

In particular, the semi-finished product 1 may be produced with a first predefined shape or configuration, preferably a substantially planar, or plate-like, or two-dimensional shape or configuration, with portions that are stiffer and intermediate portions that are less stiff and provided with hinge areas or preferential-folding areas (which are, for example, obtained following upon localized heating of the above areas, or exploiting an elastic-hinge function thereof). In this way, the semi-finished product 1 may then be made to assume a second, or different, shape or configuration, in particular a substantially three-dimensional shape or configuration. In various embodiments, in the aforesaid second, or different, shape or configuration, at least some of the stiffer regions (4, 5, 6) of the semi-finished product are folded or inclined with respect to the aforesaid first shape or configuration, and/or rise with respect to one or more other stiffer regions (4, 5, 6). Preferentially, the aforesaid second, or different, shape or configuration corresponds or substantially corresponds to that of the final heater device 1′.

The possibility of folding the semi-finished product 1 is facilitated also by the possibility of easy deformation of the connection bodies of the various heaters provided and/or of the corresponding connection conductors.

The substantially planar, or laminar, or two-dimensional shape of the semi-finished product 1 facilitates the various steps of production of the heater device 1′, considering, for example, the reduced encumbrance of the semi-finished product itself (for example, for requirements of warehousing and/or transport), which can be possibly folded into the final shape just before effective use (for example, prior to shipping or during the final installation stages).

It should likewise be emphasized that, in the stage of assembly of the semi-finished product 1, the various heaters may be conveniently arranged on a first casing part (i.e., the part 11, which may be considered a lower positioning part), which is itself substantially plane. The aforesaid first casing part may have a substantially plane, or possibly slightly inclined or curved, shape, in any case designed to enable, during assembly, maintenance of the position of the heaters 20, 21 in the casing 11, also in the presence of just the force of gravity, thus facilitating the assembly operations.

The various heaters set on the first casing part may conveniently be electrically connected to the power-supply conductors provided. The casing body of the semi-finished product can then be easily closed via a second casing part (i.e., the part 10, which may be considered an upper closing part), it being possible to weld or glue or couple in any way the two casing parts conveniently thanks to their still substantially plane configuration. The very welding or gluing between the two casing half-bodies made of polymer may be facilitated by the aforesaid substantially plane, or possibly slightly inclined or curved configuration, for example when ultrasound, or laser, or hot-blade welding is carried out, thus simplifying the corresponding welding equipment (since it is possible to carry out welding on a profile that substantially lies in one and the same plane, the reliability of the weld itself is increased, and consequently the reliability of sealed closing and protection of the casing body with respect to the external environment). Likewise, in the case where the two half-bodies are rendered fixed via gluing, the substantially plane, or possibly slightly inclined or curved, shape may facilitate distribution of an adhesive along the perimeter of the casing parts, considering a perimeter that is substantially two-dimensional. For this purpose, the adhesive may be distributed and remain in position along the perimeter by the force of gravity alone.

The invention likewise enables a considerable simplification also of the production equipment and hence a reduction in the overall costs of the final heater device (consider, for example, that automatic equipment for welding or gluing along the edges of surfaces that rise vertically and are oriented in various directions, such as the edges and faces of a parallelepiped, is very complex and costly, since it must envisage complex three-dimensional movements, i.e., at least movements along axes X, Y, Z, of the product and/or of the welding or gluing head: this drawback does not exist in the case of the invention).

It should in any case be emphasized that the semi-finished product according to the invention may be used directly as heater device also in its substantially plane configuration. From FIGS. 1 and 2, it will be appreciated, for example, that the semi-finished product 1 could be used for heating a generic wall (for example of a tank) by setting it up against the aforesaid wall in the configuration illustrated, for example exploiting the appendages 5a, 5b for fixing it in position.

Other advantages are linked to the particular embodiment of the heaters used, which are also built in a simple and inexpensive way in so far as they can be obtained as lengths of a further semi-finished product of heater substantially having the shape of strip or web that can be produced and advantageously stored in a compact form, for example in the form of a roll or else folded on itself, and then be subsequently cut to the desired length.

The fact that the connection bodies of the heaters include mesh structures at least partially embedded in the PTC-effect material of the heating bodies ensures a reliable electrical and mechanical connection, at the same time countering risks of separation or detachment between the parts in question. The fact that the meshed structure used for electrical and mechanical connection of the various heating bodies is preferentially relatively extensive and dense ensures a good surface of adhesion and contact between the connection bodies and the PTC-effect material, with optimal distribution and intensity of the electric current. The fact that the heating bodies are relatively stiff and the intermediate portions of the connection bodies are of a reduced thickness and relatively flexible or deformable, possibly in a plastic way, enables a structure to be obtained that can be easily adapted or integrated in the semi-finished product of heater device described. The portions of the connection bodies that extend in intermediate positions between two heating bodies may function not only as hinge or deformation areas, but also as compensation areas for recovery of possible dimensional variations (in particular, dimensional variations due to thermal variations, such as expansion or contraction during the operating cycles of heating and subsequent cooling).

The fact that the semi-finished product according to the invention is provided with folding areas may possibly enable at least partial adaptation of the shape of the heater device during the operations of installation on a different device or component, such as installation in the tank of a vehicle.

The fact of providing a casing having stiffer parts, suitable to be brought to assume a stable three-dimensional shape, also ensures an operation that is as a whole more reliable, in particular as compared to completely flexible heater devices. For instance, some flexible heaters mounted within tanks of vehicles are liable to being continuously moved by the liquid while the vehicle is travelling. This continuous movement, albeit limited, could in time lead to failure due to fatigue of the flexible heater device, for example of its electrical conductors and/or of its heaters, or albeit minimal alterations or reductions in the section of the electrical conductors and/or heaters, which could lead to malfunctioning.

It is clear that numerous variations may be made by the person skilled in the branch to the electric heater device described by way of example, without thereby departing from the scope of the invention, as defined in the ensuing claims.

As has already been mentioned, the number of foldable regions or walls of the semi-finished product according to the invention may vary according to the needs, and may not necessarily be such as to define a closed peripheral profile for the final heater device.

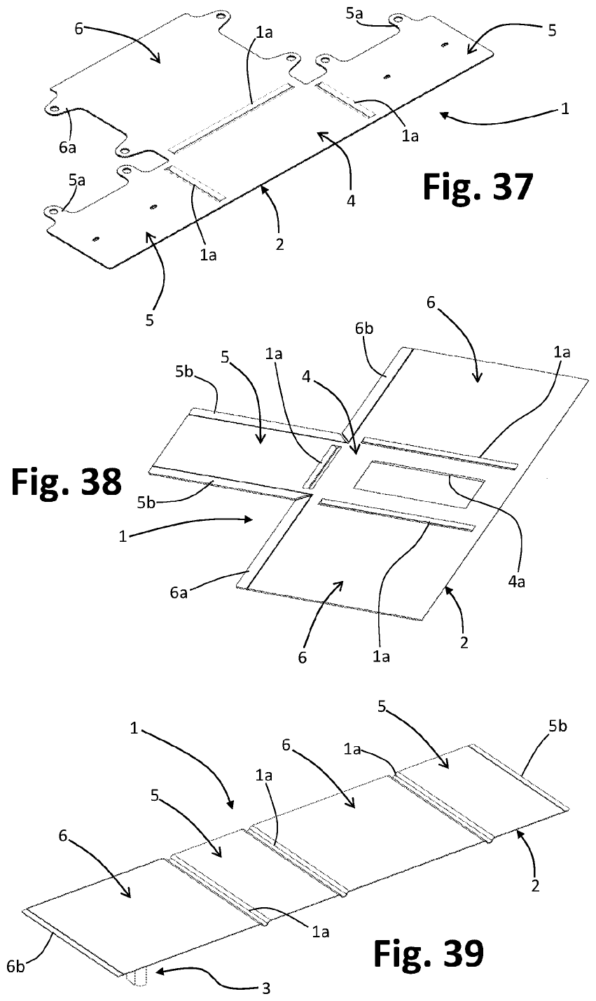

FIG. 37 illustrates, for example, a semi-finished product 1 of the type illustrated to FIGS. 1-2, but having a substantially T-shaped profile, i.e, that includes, in addition to the region/wall 4, just three peripheral regions/walls, namely two narrower walls 5 and one wider wall 6. Likewise, FIG. 38 illustrates a semi-finished product 1 of the type shown in FIGS. 16-17, but that includes, in addition to the region/wall 4, two wider walls 6 and just one narrower wall 5. FIG. 38 also shows how, in possible variant embodiments, the region/wall 4 may be without heaters and/or may be provided with at least one passage 4a.

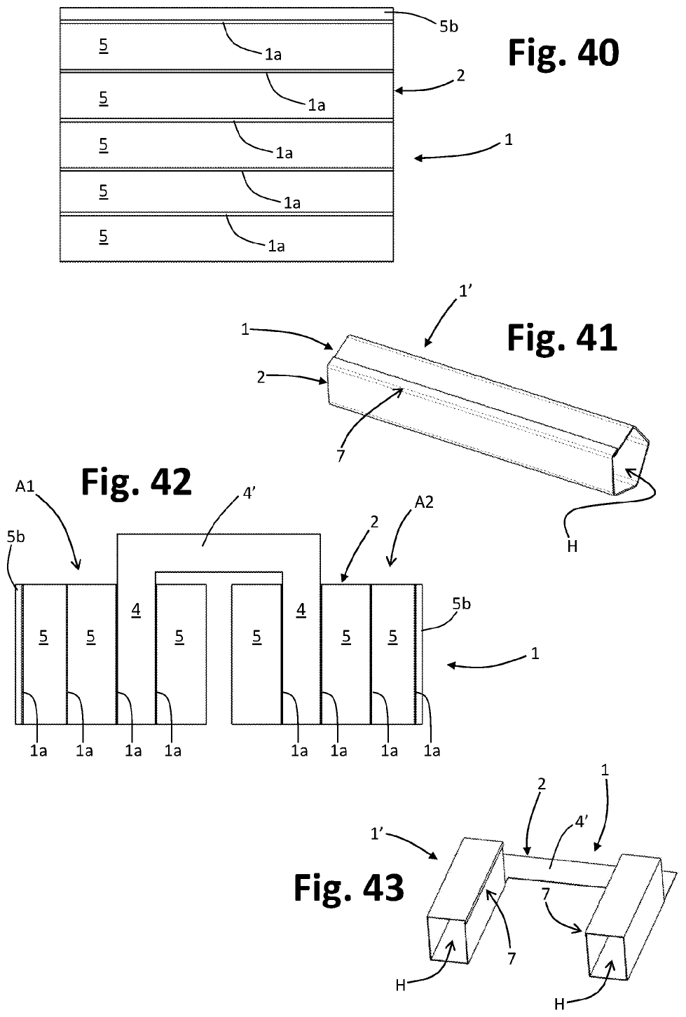

FIG. 39 illustrates, instead, a semi-finished product 1 of the type shown in FIGS. 26-27, but without the region/wall 4. In such an embodiment, the connector body 3 is associated to one of the walls 5, 6, and the geometry of the housing 11c and of the connection conductors 22-23 is modified accordingly. The heater device obtained from the semi-finished product 1 of FIG. 39 will hence present a substantially tubular configuration with a substantially polygonal cross-section, open at both of the axial ends. A similar configuration is illustrated in FIG. 40, where the semi-finished product 1 includes five regions 5 and five folding areas 1a, an end region 5 being provided with a longitudinal joining edge 5b. As shown in FIG. 41, following upon folding at the areas 1a and formation of the joining area 7, for example via gluing or welding, the semi-finished product 1 assumes a different configuration, substantially forming a heater device 1′ having a tubular shape, here with a substantially pentagonal cross section, which can be used, for example, for providing ducts or duct coatings for heating fluids, such as ducts or duct coatings for heating liquids or air in a vehicle, or else for heating liquids in a tank (for example, for heating a liquid in a tank of a vehicle, the movement of which could facilitate the flow of the liquid itself in the heater, thus improving heat exchange).

FIGS. 42-43 illustrate how, in possible variant embodiments, a semi-finished product according to the invention may include a number of portions, each provided with respective regions and folding areas, where each portion is prearranged so that it will assume, following upon folding, a respective three-dimensional configuration. In the case of FIG. 42, the semi-finished product 1 includes two distinct portions A1 and A2, generally parallel and coplanar, each comprising three regions/walls 5 and one region/wall 4, the two portions A1 and A2 being connected together: in the example, an additional region/wall is purposely provided, designated by 4′, which preferably connects together the regions 4 of the two portions.

In the example, the two end regions 5 of each portion A1, A2 have a respective longitudinal joining edge 5b. As illustrated in FIG. 43, following upon folding of each portion A1, A2, at the areas 1a, and formation of the joining area 7, exploiting the edges 5b, the semi-finished product 1 assumes a three-dimensional configuration to constitute a heater device 1′ distinguished by the presence of two tubular shapes, which here have a substantially quadrangular cross section. Of course, the two aforesaid tubular shapes may also be understood as two distinct heater devices, which can be supplied electrically independently of one another, or else may constitute a single heater with electrical supply in common. The joining region/wall 4′ does not necessarily have to be provided internally with electrical conductors and heaters, it also being possible, if need be, for it to be cut or removed in order to obtain two distinct tubular heater devices.

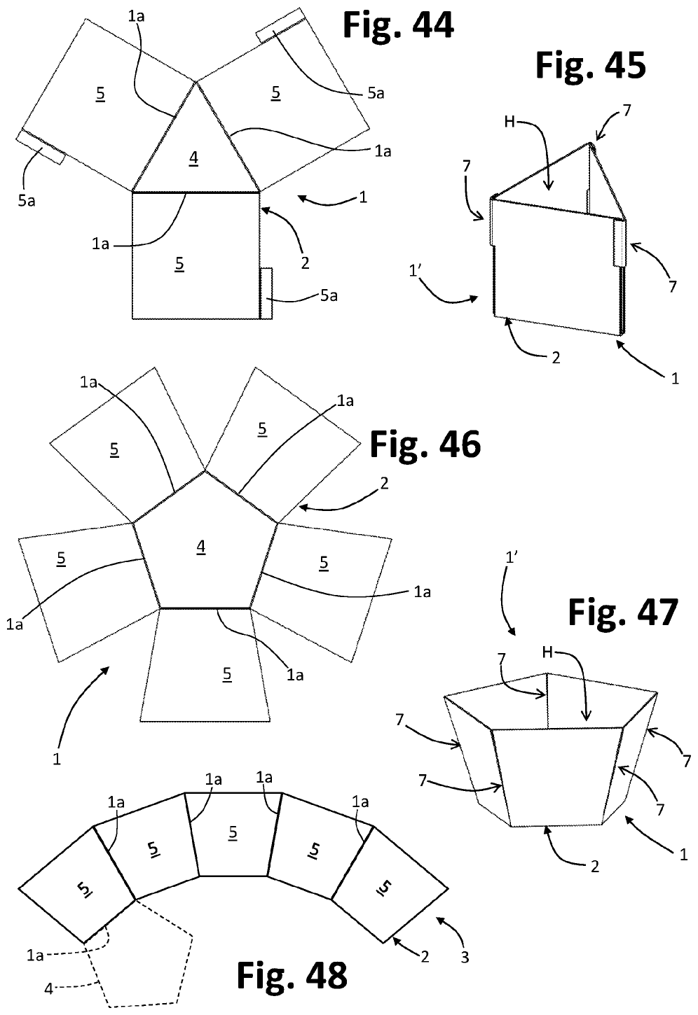

FIG. 44 illustrates the case of a semi-finished product 1 having a substantially Y-shaped profile, i.e., with one central region 4 that is substantially triangular and three peripheral regions 5 that are substantially quadrangular, each of which is provided with a coupling or fixing element 5a, while FIG. 45 illustrates the heater device 1′ that can be obtained following upon folding of the semi-finished product 1, which in this case will have a cavity H closed at one end that has a substantially triangular cross section.

In various embodiments exemplified previously, the peripheral regions or walls 5 or 6 extend, in their folded configuration, at approximately 90° with respect to the corresponding central region or wall 4. It will be appreciated, however, that the semi-finished product could be conveniently prearranged for enabling also an arrangement of the aforesaid walls 5, 6 with a different inclination, for example converging or else diverging. For instance, the central region could have a triangular, or quadrangular, or polygonal profile, and the peripheral regions could be trapezial in order to obtain a heater device having a flared shape, i.e., with walls inclined outwards. An example of this type is illustrated in FIG. 46, where the central region 4 has a profile substantially shaped like a pentagon, and the peripheral regions 5 have a profile substantially shaped like an isosceles trapezium with the minor base corresponding to the respective folding area 1a. Following upon folding, as illustrated in FIG. 47, a heater device 1′ with a generally flared shape may be obtained, which defines a cavity H that has a corresponding shape. In this example, the lateral edges of the peripheral regions 5 may be directly welded together, it remaining understood that, also in this case, the edges may be shaped so as to define respective coupling or fixing elements or areas, for example of the type illustrated in FIG. 44.

In other embodiments (not represented), the central region 4 could have a triangular, or quadrangular, or polygonal profile, and the peripheral regions could be shaped like isosceles trapeziums with their major bases corresponding to the sides of the central region 4, i.e., to the respective folding areas 1a; in this way, following upon folding, a heater device may be obtained having a generally frustopyramidal shape, which defines a cavity H having a substantially corresponding shape (i.e., a shape opposite to that of FIG. 47).

Of course, a substantially flared configuration may be provided also to obtain tubular configurations. For instance, FIG. 48 illustrates a semi-finished product 1 including a succession of first regions 5 with trapezial profile, in particular a profile shaped like an isosceles trapezium, where each folding area 1a substantially corresponds to an inclined side of the trapezium. Following upon folding at the areas 1a, it is possible to obtain a heater device 1′ similar to that of FIG. 47, but with a tubular cavity H (i.e., without a closing wall at an axial end). It should, on the other hand, be noted that, by providing in the semi-finished product 1 of FIG. 48 a further region such as the one designated by 4, it is possible to obtain a device 1′, as illustrated in FIG. 47.

The folding areas 1a, instead of being provided as shaped or grooved areas of the casing, could comprise flexible portions made of elastomeric material, which perform the function of hinge, for example being overmoulded on other regions or portions of casing made of a substantially rigid polymer and/or with the elastomeric material that itself also forms at least one portion of the casing and/or of a region thereof.

A number of heaters 20 and/or 21 welded together may also be understood as forming a single heater of the semi-finished product. A single heater set within the casing of a semi-finished product according to the invention could also include a single flexible electrical-connection support or a single flexible printed-circuit board (PCB), for example with electrical paths, extending between which are heating elements made of resistive material, for instance, overmoulded heating elements made of resistive or PTC polymer or heating elements deposited with electrically conductive or PTC ink. Such a single flexible heater may be mounted in a way substantially similar to what has been described previously within the casing of the semi-finished product in order to enable the latter to be subsequently folded in the purposely provided predefined areas, as explained above. Preferentially, also in these embodiments, the end semi-finished product is at least in part substantially stiff, or is able to assume subsequently a substantially stiff three-dimensional shape following upon folding of the casing.

1. An electric heater device semi-finished product, having a casing body defining a housing for one or more electric heaters,
wherein the electric heater or each electric heater comprises:
at least two connection bodies, which extend at least in part substantially alongside or parallel to one another in a respective length direction and are at least in part flexible or deformable; and
a plurality of heating bodies, which are set at a distance from one another in the length direction and extend generally transverse to the length direction, each heating body being in electrical contact with the at least two connection bodies,
wherein the casing body has a first or predefined configuration, substantially two-dimensional, and is prearranged for being folded at an angle at substantially predetermined folding areas, which define in the casing body a plurality of regions that are relatively stiff and designed to be folded at an angle with respect to one another at one said folding area, in such a way that a second or different configuration, substantially three-dimensional, may be given to the casing body.

2. The semi-finished product according to claim 1, wherein at least a first one of said regions is prearranged for being coupled at least in part to at least a second one of said regions to enable the casing body to maintain stably said second or different configuration.

3. The semi-finished product according to claim 2, wherein the at least one first region has at least one coupling or fixing element or a longitudinal edge, which is prearranged for being coupled to a corresponding coupling or fixing element or longitudinal edge of the at least one second region.

4. The semi-finished product according to claim 1, wherein in one or more of said regions a respective portion of said housing is provided, configured for positioning one or more of said electric heaters.

5. The semi-finished product according to claim 1, wherein the one or more electric heaters comprises/comprise at least one of the following:
first heaters having a first heat-emission power, and second heaters having a second heat-emission power, the second heat-emission power being higher than the first heat-emission power;
first heaters suitable to be electrically supplied in an independent way with respect to second heaters.

6. The semi-finished product according to claim 1, wherein the plurality of regions comprises:
a central region and a plurality of peripheral regions, between the central region and each peripheral region one said substantially predetermined folding area being provided, in such a way that the peripheral regions can be folded at an angle relative to the central region; or else
a succession of regions, which are set alongside one another in a first direction, between two successive regions set alongside one another one said substantially predetermined folding area being provided, in such a way that the regions of the succession of regions can be folded at an angle towards one another.

7. The semi-finished product according to claim 1, wherein the casing body in said second or different configuration delimits a substantially hollow volume.

8. The semi-finished product according to claim 1, wherein an electrical connector body is associated to one of said regions.

9. The semi-finished product according to claim 1, wherein the housing is configured for positioning electrical conductors, for electrical connection a plurality of said electric heaters.

10. The semi-finished product according to claim 1, wherein the casing body comprises two casing parts, which are coupled together at least at their peripheral profiles, at least one casing part defining at least one respective portion of the housing.

11. The semi-finished product according to claim 1, wherein:
each heating body of at least one said electric heater includes a resistive material; and
each of the at least two connection bodies comprises electrical- and mechanical-connection parts, which have a mesh structure that is at least partially embedded or englobed in the polymer-based material.

12. The semi-finished product according to claim 11, wherein at least one from among:
the mesh structure of the electrical- and mechanical-connection parts is formed by the interweaving or criss-crossing of substantially threadlike elements of electrically conductive material, or else is formed by a single element of electrically conductive material having a substantially meshed shape;
each heating body has two opposite major faces, and the mesh structure of each electrical- and mechanical-connection part extends substantially parallel to at least one major face of the corresponding heating body;
the mesh structure of each electrical- and mechanical-connection part is at least partially embedded in the corresponding heating body on a corresponding face of the latter, or else each heating body is a body overmoulded at least in part on the mesh structures of the corresponding electrical- and mechanical-connection parts of the at least two connection bodies;
each of the at least two connection bodies is made up of a number of parts, which comprise a first element that extends in the length direction and a plurality of second elements that extend in a direction transverse to the first element, at least the second elements each comprising a respective mesh structure having a first portion that is at least partially embedded or englobed in the polymer-based material of a corresponding heating body, and a second portion that is superimposed on, or connected at least in part to, the first element, in electrical and mechanical contact therewith.

13. An electric heater device, comprising a semi-finished product according to claim 1.

14. An electric heater for use in a semi-finished product according to claim 1, the electric heater having a structure that extends in a length direction, the structure comprising:
at least two connection bodies, which extend substantially alongside or parallel to one another in the length direction and are at least in part flexible or deformable; and
a plurality of heating bodies, each heating body including a resistive material,
wherein the heating bodies are set at a distance from one another in the length direction and extend generally transverse to the length direction,
wherein the resistive material is a polymer-based material that is in electrical contact with the at least two connection bodies,
wherein each of the at least two connection bodies comprises electrical- and mechanical-connection parts, which have a mesh structure that is at least partially embedded or englobed in the polymer-based material.

15. A method for obtaining a semi-finished product of an electric heater device according to claim 1, comprising the steps of:
i) providing a first casing part and a second casing part;
ii) providing one or more electric heaters;
iii) providing a plurality of electrical conductors for electrical connection of the one or more electric heaters;
iv) electrically connecting the one or more electric heaters to the plurality of electrical conductors;
iii) constraining the first casing part and the second casing part at least at an outer profile thereof, with the one or more electric heaters connected to the plurality of electrical conductors therebetween, to form a casing body of the semi-finished product having a first or predefined configuration, substantially two-dimensional,
wherein:
at least one of the first casing part and the second casing part is formed with a respective housing for the one or more electric heaters and the plurality of electrical conductors; and
at least one from among:
the first casing part,
the second casing part,
the one or more electric heaters,
the plurality of electrical conductors
is prearranged in such a way that in the casing body of the semi-finished product a plurality of substantially predetermined folding areas are provided, which define in the casing body a plurality of regions that are relatively stiff and designed to be folded with respect to one another in one said substantially predetermined folding area, in such a way that a second or different configuration, substantially three-dimensional, can be bestowed upon the casing body.

16. A method for producing an electric heater device comprising the steps of:
providing a semi-finished product according to claim 1 in the respective first or predefined configuration, substantially two-dimensional;
folding the semi-finished product at the plurality of substantially predetermined folding areas to confer the semi-finished product the second or different configuration, substantially three-dimensional; and
constraining at least a first one of said regions to at least a second one of said regions to enable the semi-finished product to maintain the second or different configuration.

17. An electric heater device, having a casing body defining a housing for one or more electric heaters, wherein the casing body has a first or predefined manufacturing configuration, substantially two-dimensional, and is prearranged for being folded at an angle in one or more substantially predetermined folding areas to define a plurality of regions, which are relatively stiff and are folded or designed to be folded with respect to one another in such a way that a second or different configuration, substantially three-dimensional, can be bestowed upon the casing body.

18. The semi-finished product according to claim 4, wherein said respective portion is configured for positioning a plurality of said electric heaters in a configuration where they are generally set alongside one another.

19. The semi-finished product according to claim 9, wherein the electrical conductors have respective portions that extend in a transverse direction with respect to the length direction of the at least two connection bodies of a corresponding electric heater.

20. The semi-finished product according to claim 11, wherein the resistive material is a polymer-based material having PTC effect.
